(19) United States
(12) Patent Application Publication
(10) Pub. No.: US 2026/0293351 A1
(43) Pub. Date: Sep. 24, 2026

(54) PHOTOELECTRIC CONVERSION DEVICE

(71) Applicant: CANON KABUSHIKI KAISHA, TOKYO (JP)

(72) Inventors: RYO YOSHIDA, VICTORIA (CA); YOSHIYUKI HAYASHI, TOKYO (JP)

(21) Appl. No.: 19/562,862

(22) Filed: Mar. 11, 2026

(30) Foreign Application Priority Data
Mar. 21, 2025 (JP) 2025-047301

(51) Int. Cl. H10F 39/00

(52) U.S. Cl. CPC H10F 39/807; H10F 39/8023

(57) ABSTRACT

A photoelectric conversion device includes a substrate having a first surface and a second surface that is opposite to the first surface and is a light incident surface. The pixels are arranged on the substrate, the pixels each have photoelectric conversion units, between the photoelectric conversion units included in one of the pixels, a first trench extending from the second surface toward the first surface is arranged, between the pixels, a second trench extending from the first surface toward the second surface is arranged, the first trench and the second trench have an intersecting portion that intersects each other, the first trench is separated from the first surface, and an end portion on the first surface side of the first trench in the intersecting portion is positioned on the second surface side relative to an end portion on the first surface side in a non-intersecting portion.

### BACKGROUND

### Field of the Technology

The present disclosure relates to a photoelectric conversion device that converts light into an electrical signal.

### Description of the Related Art

A technology has been proposed that suppresses crosstalk between a plurality of photoelectric conversion units in a photoelectric conversion device. In U.S. Patent Publication No. 2016/0056200, a configuration is disclosed in which a deep trench is arranged between a plurality of photoelectric conversion units in a photoelectric conversion device.

In a photoelectric conversion device, in order to suppress a decrease in linearity of signal intensity of an output signal with respect to incident light, it is preferable to provide a charge leak path between adjacent photoelectric conversion units. However, with the technology disclosed in U.S. Patent Publication No. 2016/0056200, there is a possibility that formation of a leak path between photoelectric conversion units cannot be suitably achieved.

### SUMMARY

Therefore, the present disclosure provides a trench structure capable of achieving both suppression of deterioration of crosstalk and suppression of a decrease in linearity of signal intensity in a photoelectric conversion device.

According to a first aspect of the present disclosure, a photoelectric conversion device includes a substrate having a first surface and a second surface that is a surface on a side opposite to the first surface and is a light incident surface, wherein a plurality of pixels are arranged on the substrate, the plurality of pixels each have a plurality of photoelectric conversion units, between the plurality of photoelectric conversion units included in one pixel of the plurality of pixels, a first trench extending from the second surface toward the first surface is arranged, between the plurality of pixels, a second trench extending from the first surface toward the second surface is arranged, in a plan view of the substrate, the first trench and the second trench have an intersecting portion where the first trench and the second trench intersect with each other, the first trench is separated from the first surface, and an end portion on the first surface side of the first trench in the intersecting portion is positioned on the second surface side relative to an end portion on the first surface side of the first trench in a non-intersecting portion where the first trench and the second trench do not intersect in the plan view.

According to a second aspect of the present disclosure, a photoelectric conversion device includes a substrate having a first surface and a second surface that is a surface on a side opposite to the first surface and is a light incident surface, wherein a plurality of pixels are arranged on the substrate, the plurality of pixels each have a plurality of photoelectric conversion units, between the plurality of photoelectric conversion units included in one pixel of the plurality of pixels, a first trench extending from the second surface toward the first surface is arranged, between the plurality of pixels, a second trench extending from the first surface toward the second surface is arranged, in a plan view of the substrate, the first trench and the second trench have an intersecting portion where the first trench and the second trench intersect with each other, the first trench is separated from the first surface, and an end portion on the second surface side of the second trench in the intersecting portion is positioned on the first surface side relative to an end portion on the second surface side of the second trench in a non-intersecting portion where the first trench and the second trench do not intersect in the plan view.

According to a third aspect of the present disclosure, a photoelectric conversion device includes a substrate having a first surface and a second surface that is a surface on a side opposite to the first surface and is a light incident surface, wherein a plurality of pixels are arranged on the substrate, the plurality of pixels each have a plurality of photoelectric conversion units, between the plurality of photoelectric conversion units included in one pixel of the plurality of pixels, a first trench extending from the second surface toward the first surface is arranged, between the plurality of pixels, a second trench extending from the first surface toward the second surface is arranged, in a plan view of the substrate, the first trench and the second trench do not intersect, and a P-type diffusion layer is arranged between the first trench and the second trench, and the first trench is separated from the first surface.

Features of the present disclosure will become apparent from the following description of embodiments with reference to the attached drawings. The following description of embodiments is described by way of example.

### BRIEF DESCRIPTION OF THE DRAWINGS

FIG. 1 is a diagram schematically showing a photoelectric conversion device according to a first embodiment.

FIG. 2 is a plan view showing a part of a light-receiving pixel region of the photoelectric conversion device according to the first embodiment.

FIG. 3 is a cross-sectional view of the photoelectric conversion device taken along line A-A' of FIG. 2.

FIG. 4 is a cross-sectional view of the photoelectric conversion device taken along line B-B' of FIG. 2.

FIG. 5 is a cross-sectional view of the photoelectric conversion device taken along line C-C' of FIG. 2.

FIGS. 6A to 6E are diagrams showing an example of a manufacturing method of a circuit substrate of the photoelectric conversion device according to the first embodiment.

FIGS. 7A to 7E are diagrams showing an example of a manufacturing method of a PD substrate of the photoelectric conversion device according to the first embodiment.

FIGS. 8A and 8B are diagrams showing an example of a manufacturing method of the photoelectric conversion device according to the first embodiment.

FIGS. 9A and 9B are diagrams showing an example of a manufacturing method of the photoelectric conversion device according to the first embodiment.

FIG. 10 is a plan view showing a part of a light-receiving pixel region of a photoelectric conversion device according to Modification Example 1.

FIG. 11 is a plan view showing a part of a light-receiving pixel region of a photoelectric conversion device according to a second embodiment.

FIG. 12 is a cross-sectional view of the photoelectric conversion device taken along line A-A' of FIG. 11.

FIG. 13 is a cross-sectional view of the photoelectric conversion device taken along line B-B' of FIG. 11.

FIG. 14 is a cross-sectional view of the photoelectric conversion device taken along line C-C' of FIG. 11.

FIG. 15 is a plan view showing a part of a light-receiving pixel region of a photoelectric conversion device according to Modification Example 2.

FIG. 16 is a plan view showing a part of a light-receiving pixel region of a photoelectric conversion device according to a third embodiment.

FIG. 17 is a cross-sectional view of the photoelectric conversion device taken along line A-A' of FIG. 16.

FIG. 18 is a plan view showing a part of a light-receiving pixel region of a photoelectric conversion device according to a fourth embodiment.

FIG. 19 is a cross-sectional view of the photoelectric conversion device taken along line A-A' of FIG. 18.

FIG. 20 is a plan view showing a part of a light-receiving pixel region of a photoelectric conversion device according to a fifth embodiment.

FIG. 21 is a cross-sectional view of the photoelectric conversion device taken along line A-A' of FIG. 20.

FIG. 22 is a diagram explaining a photoelectric conversion system according to a sixth embodiment.

FIGS. 23A and 23B are diagrams explaining a photoelectric conversion system and a moving body according to a seventh embodiment.

FIG. 24 is a diagram explaining a distance image sensor according to an eighth embodiment.

FIG. 25 is a diagram explaining an endoscopic surgery system according to a ninth embodiment.

FIGS. 26A and 26B are diagrams explaining smart glasses according to a tenth embodiment.

FIGS. 27A and 27B are diagrams explaining an electronic device according to an eleventh embodiment.

FIG. 28 is a diagram explaining an X-ray CT device according to a twelfth embodiment.

FIG. 29 is a diagram explaining equipment according to a thirteenth embodiment.

### DESCRIPTION OF THE EMBODIMENTS

The following embodiments are intended to embody the technical idea of the present disclosure, and do not limit the present disclosure. The sizes and positional relationships of members shown in the drawings may be exaggerated to clarify the description. In the following description, the same components are denoted by the same reference numerals, and descriptions thereof may be omitted.

Hereinbelow, referring to the drawings, embodiments of the present disclosure will be described in detail. In the following description, terms which indicate specific directions or positions (e.g., "up", "down", "right", "left", and other terms including such terms) are used as necessary. Such terms are used for ease of understanding of the embodiments with reference to the drawings, and are not intended to limit the technical scope of the present disclosure by the meanings of the terms.

In the present specification, a plan view is a plan view of a substrate on which pixels of a photoelectric conversion device are arranged, and is viewing from a direction perpendicular to a light incident surface of a semiconductor layer. Further, a cross-sectional view means viewing from a direction perpendicular to the light incident surface of the semiconductor layer. In addition, when the light incident surface of the semiconductor layer is a rough surface when viewed microscopically, a plan view is defined with reference to the light incident surface of the semiconductor layer when viewed macroscopically.

### First Embodiment

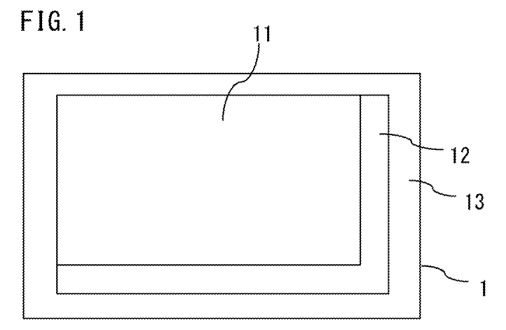

A photoelectric conversion device according to the first embodiment will be explained with reference to FIGS. 1 to 9A and 9B. FIG. 1 is a diagram schematically showing a schematic configuration of a photoelectric conversion device 1 according to the present embodiment.

As shown in FIG. 1, the photoelectric conversion device 1 includes a light-receiving pixel region 11, a light-shielding pixel region 12, and a peripheral region 13. In the light-receiving pixel region 11, unit pixels including photoelectric conversion elements are arranged two-dimensionally in M rows and N columns (M and N are natural numbers). Further, in the light-shielding pixel region 12 as well, unit pixels including photoelectric conversion elements are arranged two-dimensionally.

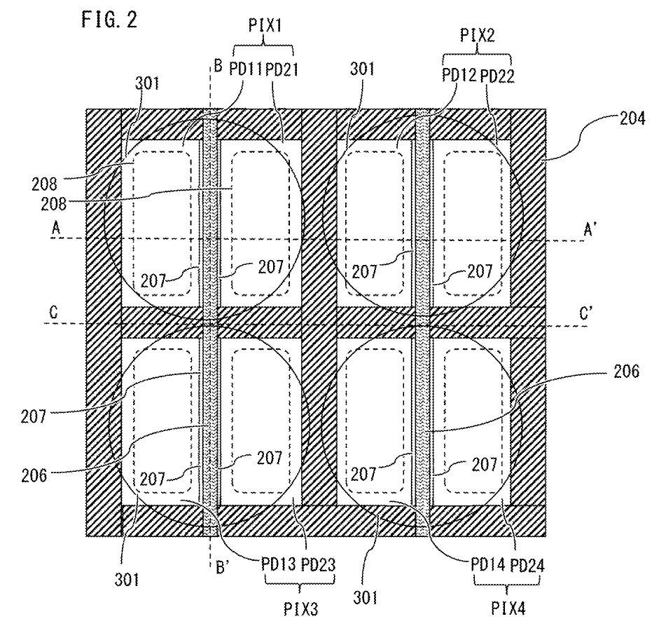

FIG. 2 shows a plan view when a part of the light-receiving pixel region 11 of the photoelectric conversion device 1 in the present embodiment is viewed from the incident light side. In FIG. 2, pixel units PIX1 to PIX4 arranged in 2 rows and 2 columns in a plan view are shown. In the pixel unit PIX1, photodiodes (PD) PD11 and PD21 as examples of photoelectric conversion elements that convert incident light into charges are arranged. A microlens 301 for efficiently focusing incident light onto the photodiodes PD11 and PD21 is arranged on the photodiodes PD11 and PD21. In the present embodiment, the photodiodes PD11 and PD21 are configured to share one microlens 301. The pixel units PIX2 to PIX4 also include photodiodes PD12 and PD22, photodiodes PD13 and PD23, and photodiodes PD14 and PD24, respectively, and have a configuration similar to PIX1. The photodiodes PD11 to 14 and PD21 to 24 are a plurality of photoelectric conversion units arranged in a direction substantially parallel to a first main surface 201A described later. Further, the photodiodes PD11 to 14 and PD21 to 24 are divided into a plurality of pixels such that one pixel corresponds to multiple photoelectric conversion units.

As shown in FIG. 2, between the pixel unit PIX1 and the pixel unit PIX2 that are adjacent to each other in a plan view, between the pixel unit PIX1 and the pixel unit PIX3, between the pixel unit PIX2 and the pixel unit PIX4, and between the pixel unit PIX3 and the pixel unit PIX4, inter-pixel trenches 204 are formed. By the inter-pixel trenches 204, crosstalk between pixel units adjacent across the inter-pixel trench 204 is suppressed. Further, in the pixel unit PIX1, between the photodiodes PD11 and PD21, an inter-PD trench 206 for preventing crosstalk between PDs is formed. Similarly, in the pixel units PIX2 to PIX4 as well, inter-PD trenches 206 are formed. In the present embodiment, the inter-PD trench 206 is a first trench extending from a second main surface 201B toward a first main surface 201A described later. Further, the inter-pixel trench 204 is a second trench extending from the first main surface 201A toward the second main surface 201B described later.

Further, the photoelectric conversion device 1 according to the present embodiment has a portion where the inter-PD trench 206 and the inter-pixel trench 204 intersect each other in a plan view, as shown in FIG. 2. Thereby, in a plan view, since the inter-PD trench 206 and the inter-pixel trench 204 are arranged so as to be connected to each other, crosstalk between the photodiodes PD11 and PD21 in the pixel unit PIX1 is suitably suppressed. Similarly, crosstalk between the photodiodes PD12 and PD22 of the pixel unit PIX2, crosstalk between the photodiodes PD13 and PD23 of the pixel unit PIX3, and crosstalk between the photodiodes PD14 and PD24 of the pixel unit PIX4 are also suitably suppressed.

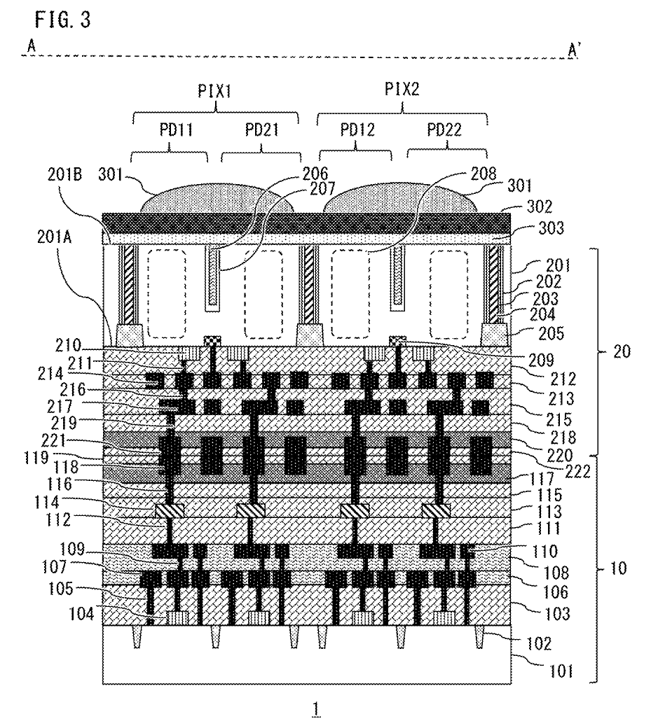

FIG. 3 shows a cross-sectional view of the photoelectric conversion device 1 taken along line A-A' of FIG. 2. The photoelectric conversion device 1 is configured by a stacked structure of a circuit substrate 10 and a PD substrate 20, and the circuit substrate 10 and the PD substrate 20 are electrically connected by a first bonding electrode 118 and a second bonding electrode 221.

The circuit substrate 10 includes a signal processing circuit for performing signal processing on signals output from pixels. Specifically, on a first semiconductor substrate 101, a transistor configured by source regions and drain regions (not shown) and a first gate electrode 104 arranged between both regions, a first element isolation portion 102 for isolating each transistor, and a first contact interlayer film 103 are provided. A first wiring interlayer film 106 and a first wiring 107 are formed on the first contact interlayer film 103.

The first wiring 107 is electrically connected to the transistor via a first contact plug 105. On the first wiring interlayer film 106, a second wiring interlayer film 108, a second wiring 110 formed inside of the second wiring interlayer film 108, and a first via 109 that electrically connects the second wiring 110 and the first wiring 107 are formed.

On the second wiring interlayer film 108, a first upper-layer interlayer film 111, a second upper-layer interlayer film 113, a first upper-layer wiring 114, and a first upper-layer via 112 for connecting the first upper-layer wiring 114 and the second wiring 110 are formed. Further, on the second upper-layer interlayer film 113, a first bonding interlayer film 115, a second bonding interlayer film 117, and a third bonding interlayer film 119 are formed. Further, inside of the second bonding interlayer film 117 and the third bonding interlayer film 119, a first bonding electrode 118 is formed. Further, the first bonding electrode 118 is electrically connected to the first upper-layer wiring 114 by a first bonding via 116. In the present embodiment, the circuit substrate 10 is configured by the above four wiring layers, but the total number of wiring layers may be greater than this or may be smaller than this.

The PD substrate 20 includes a second semiconductor substrate 201 having a first main surface 201A and a second main surface 201B. In the present embodiment, the first main surface 201A is a first surface, and the second main surface 201B is a second surface that is on the side opposite to the first main surface 201A and serves as a light incident surface. Further, on the first main surface 201A side of the second semiconductor substrate 201, a floating diffusion 209, a transfer electrode 210, a second contact interlayer film 212, and a second contact plug 211 are formed.

Further, below the second contact interlayer film 212, a third wiring interlayer film 213 and a third wiring 214 formed inside of the third wiring interlayer film 213 are formed. Further, below the third wiring interlayer film 213, a fourth wiring interlayer film 215 and a fourth wiring 217 formed inside of the fourth wiring interlayer film 215 are formed. The fourth wiring 217 and the third wiring 214 are electrically connected by a second via 216. Further, below the fourth wiring interlayer film 215, a fourth bonding interlayer film 218, a fifth bonding interlayer film 220, and a sixth bonding interlayer film 222 are formed, and inside of the fifth bonding interlayer film 220 and the sixth bonding interlayer film 222, a second bonding electrode 221 is formed. The second bonding electrode 221 and the fourth wiring 217 are electrically connected by a second bonding via 219. In the present embodiment, the PD substrate 20 is formed by the above three wiring layers, but the total number of wiring layers may be more or less than this.

On the second main surface 201B side of the second semiconductor substrate 201, a back surface interlayer film 303, a color filter layer 302, and a microlens 301 are arranged. In FIG. 3, inside of the second semiconductor substrate 201, photodiodes PD11, PD21, PD12, and PD22 including charge storage portions 208 are arranged. Further, between the photodiode PD11 and the photodiode PD21, an inter-PD trench 206 is formed. Similarly, between the photodiode PD12 and the photodiode PD22, an inter-PD trench 206 is formed. An end portion on the second main surface 201B side of the inter-PD trench 206 is in contact with the back surface interlayer film 303.

In the present embodiment, an end portion on the first main surface 201A side of the inter-PD trench 206 is separated from the first main surface 201A and is positioned inside of the second semiconductor substrate 201. In this manner, by providing a gap at a lower portion (first main surface 201A side) of the inter-PD trench, when charges in one photodiode of the photodiodes PD11 and PD21 are saturated, a path for moving charges to the other photodiode can be secured. The same applies to the photodiodes PD12 and PD22. Therefore, in the photoelectric conversion device 1 of the present embodiment, when high-luminance light is incident on the pixel units PIX1 and PIX2, it is expected that leakage of charges to the outside of the pixel units PIX1 and PIX2 is reduced and a decrease in linearity of signal intensity of an output signal with respect to the amount of incident light is suppressed. In addition, for the pixel units PIX3 and PIX4 as well, the above effect can be expected similarly to the pixel units PIX1 and 2.

Further, in the photoelectric conversion device 1 of the present embodiment, since a leak path is formed at a lower portion of the inter-PD trench 206, dark electrons generated from a sidewall portion of the inter-pixel trench 204 become difficult to mix with signal charges, and an effect of suppressing a decrease in linearity of signal intensity of an output signal can also be expected.

Further, as shown in FIG. 3, a first P-type diffusion layer 207 is formed on a sidewall portion of the inter-PD trench 206. By the first P-type diffusion layer 207, an effect of suppressing generation of dark electrons due to interface states at the sidewall portion of the inter-PD trench 206 is obtained. Further, between pixel units adjacent to each other among the pixel units PIX1 to PIX4, inter-pixel trenches 204 are formed. Further, as shown in FIG. 3, a second element isolation portion 205 is arranged at an end portion on the first main surface 201A side of the inter-pixel trench 204.

In the present embodiment, an end portion on the second main surface 201B side of the inter-pixel trench 204 is formed so as to be in contact with the back surface interlayer film 303, but it may be formed so as not to be in contact with the back surface interlayer film 303. It is sufficient that an end portion on the first main surface 201A side of the inter-PD trench 206 is positioned on the first main surface 201A side relative to an end portion on the second main surface 201B side of the inter-pixel trench 204. Further, as shown in FIG. 3, on a sidewall portion of the inter-pixel trench 204, a liner film 203 and a second P-type diffusion layer 202 are formed. By the second P-type diffusion layer 202, an effect of suppressing dark electrons generated around the liner film 203 is obtained.

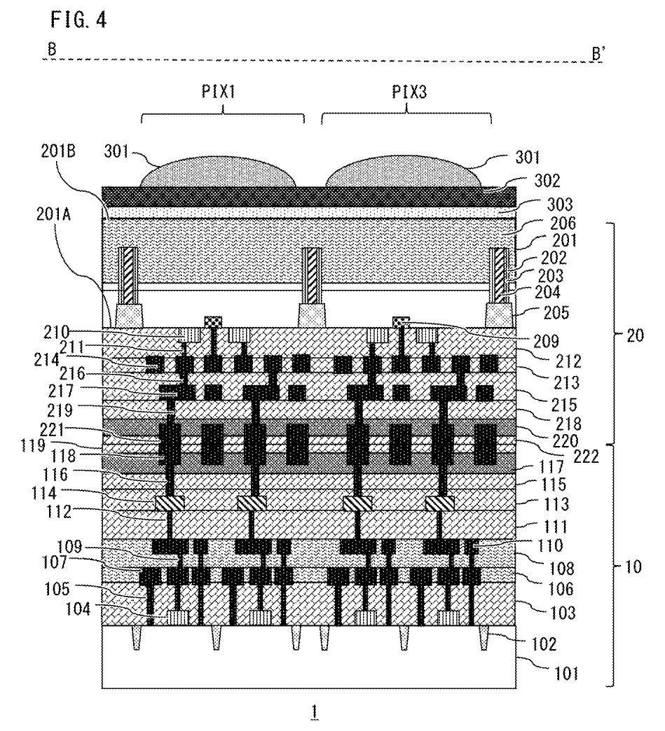

FIG. 4 shows a cross-sectional view of the photoelectric conversion device 1 taken along line B-B' of FIG. 2. As shown in FIG. 4, between the pixel unit PIX1 and the pixel unit PIX3, an inter-pixel trench 204 is formed. Further, an end portion on the second main surface 201B side of the inter-pixel trench 204 in a portion where the inter-pixel trench 204 and the inter-PD trench 206 intersect each other is positioned on the first main surface 201A side relative to the end portion in a portion where both trenches do not intersect each other (see FIG. 3).

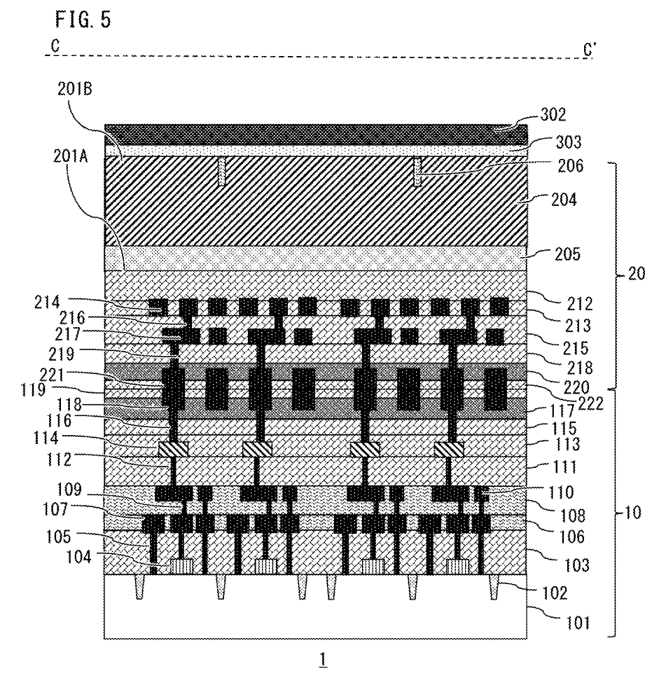

FIG. 5 shows a cross-sectional view of the photoelectric conversion device 1 taken along line C-C' of FIG. 2. As shown in FIG. 5, an end portion on the first main surface 201A side of the inter-PD trench 206 in a portion where the inter-pixel trench 204 and the inter-PD trench 206 intersect each other is positioned on the second main surface 201B side relative to the end portion in a portion where both trenches do not intersect each other (FIG. 3).

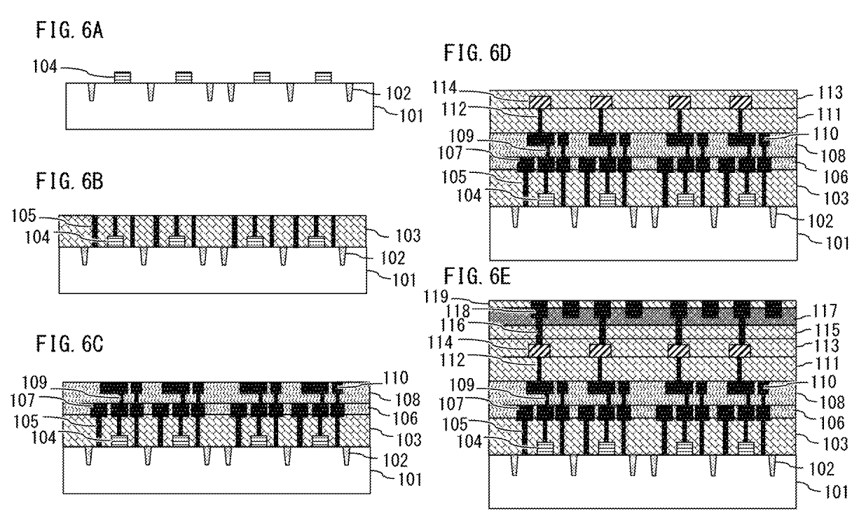

Next, an example of a manufacturing method of the photoelectric conversion device 1 in the first embodiment will be explained with reference to FIGS. 6A to 6E to 9A and 9B.

First, a manufacturing method of the circuit substrate 10 will be explained. As shown in FIG. 6A, inside of the first semiconductor substrate 101, first element isolation portions 102 are formed. The first element isolation portions 102 are formed, for example, by STI (Shallow Trench Isolation) or LOCOS (Local Oxidation of Silicon). Further, between the first element isolation portions 102, diffusion layers (not shown) such as source regions and drain regions are formed, for example, by an ion implantation method. On the first semiconductor substrate 101, a gate insulating film (not shown) and a first gate electrode 104 are formed. As the gate insulating film (not shown), silicon oxide or a High-k film may be adopted. As the first gate electrode 104, polysilicon formed, for example, by thermal CVD (Chemical Vapor Deposition) may be adopted.

Next, as shown in FIG. 6B, on the first semiconductor substrate 101, a first contact interlayer film 103 and a first contact plug 105 are formed. As the first contact interlayer film 103, for example, a silicon oxide film may be adopted. As the first contact plug 105, tungsten may be adopted.

Next, as shown in FIG. 6C, wiring layers are formed on the first contact interlayer film 103. The wiring layers are formed by using a damascene process. As the first wiring interlayer film 106 and the second wiring interlayer film 108, a stacked film of an etch stop layer such as SiC and an interlayer insulating film of a silicon oxide film or a Low-k film (for example, SiOCH) may be adopted. The first wiring 107 and the second wiring 110 are configured by a stacked film of a barrier metal (for example, tantalum) and a conductive film (for example, copper).

Next, as shown in FIG. 6D, on the second wiring interlayer film 108, a first upper-layer interlayer film 111, a first upper-layer via 112, a first upper-layer wiring 114, and a second upper-layer interlayer film 113 are formed in order. As the first upper-layer interlayer film 111 and the second upper-layer interlayer film 113, for example, silicon oxide may be adopted. The first upper-layer via 112 may be configured by tungsten, and the first upper-layer wiring 114 may be configured by aluminum.

Next, as shown in FIG. 6E, on the second upper-layer interlayer film 113, a first bonding interlayer film 115, a second bonding interlayer film 117, and a third bonding interlayer film 119 are deposited. Thereafter, a first bonding via 116 and a first bonding electrode 118 are formed by using a dual damascene process. As the first bonding interlayer film 115 and the third bonding interlayer film 119, a silicon oxide film may be adopted. Further, as the second bonding interlayer film 117, a silicon nitride film may be adopted. Further, the first bonding via 116 and the first bonding electrode 118 may be configured by a conductor containing copper.

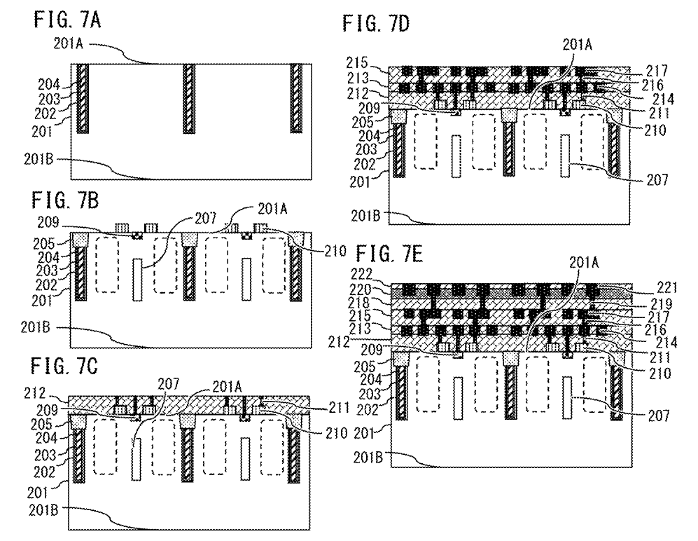

Next, a manufacturing method of the PD substrate 20 will be explained with reference to FIGS. 7A to 7E. First, as shown in FIG. 7A, grooves are formed on the first main surface 201A side of the second semiconductor substrate 201. Thereafter, by implanting boron into sidewall portions of the formed grooves using a conformal doping process such as plasma doping, gas phase doping, or solid phase diffusion, second P-type diffusion layers 202 are formed. Here, in the second P-type diffusion layer 202, boron ¹⁰B having a mass number of 10 in the P-type diffusion layer occupies not less than 10% of the mass of the entire boron.

Next, as shown in FIG. 7A, after depositing a liner film 203 (for example, a silicon oxide film), by embedding polysilicon inside of the grooves, inter-pixel trenches 204 are formed. In addition, in the present embodiment, a stacked film of the liner film 203 and polysilicon is formed inside of the grooves, but a film (for example, a silicon oxide film single layer) having a different configuration may be formed.

Next, as shown in FIG. 7B, on the first main surface 201A side of the second semiconductor substrate 201, second element isolation portions 205, first P-type diffusion layers 207, floating diffusions 209, a gate insulating film (not shown), and transfer electrodes 210 are formed. As the second element isolation portions 205, a silicon oxide film formed by an STI process may be adopted. In the present embodiment, as shown in FIG. 7B, the second element isolation portion 205 is formed at a position overlapping an end portion on the first main surface 201A side of the inter-pixel trench 204.

The first P-type diffusion layer 207 is formed by doping boron by an ion implantation method. Here, since ¹¹B is selectively doped by a mass analyzer in ion implantation, a ratio of ¹⁰B becomes smaller than an abundance ratio of isotopes in nature. Specifically, in the P-type diffusion layer, a ratio of the mass of ¹⁰B to the entire boron is less than 10%. Further, the floating diffusion 209 is formed by implanting arsenic or phosphorus by an ion implantation method. As the transfer electrode 210, for example, polysilicon may be adopted.

Next, as shown in FIG. 7C, a second contact interlayer film 212 and second contact plugs 211 are formed. As the second contact interlayer film 212 and the second contact plugs 211, a silicon oxide film and tungsten may be adopted, respectively.

Next, as shown in FIG. 7D, on the second contact interlayer film 212, a third wiring interlayer film 213, a third wiring 214, a fourth wiring interlayer film 215, and a fourth wiring 217 are formed by using a damascene process. As the third wiring interlayer film 213 and the fourth wiring interlayer film 215, a stacked film of an etch stop layer such as SiC and an interlayer insulating film of a silicon oxide film or a Low-k film (for example, SiOCH) may be adopted. Further, the third wiring 214 and the fourth wiring 217 may be configured by a stacked film of a barrier metal (for example, tantalum) and a conductive film (for example, copper).

Next, after depositing a fourth bonding interlayer film 218, a fifth bonding interlayer film 220, and a sixth bonding interlayer film 222, a second bonding via 219 and a second bonding electrode 221 are formed by using a dual damascene process. As the fourth bonding interlayer film 218 and the sixth bonding interlayer film 222, a silicon oxide film may be adopted. Further, as the fifth bonding interlayer film 220, a silicon nitride film may be adopted. Further, the second bonding via 219 and the second bonding electrode 221 may be formed of a conductor containing copper.

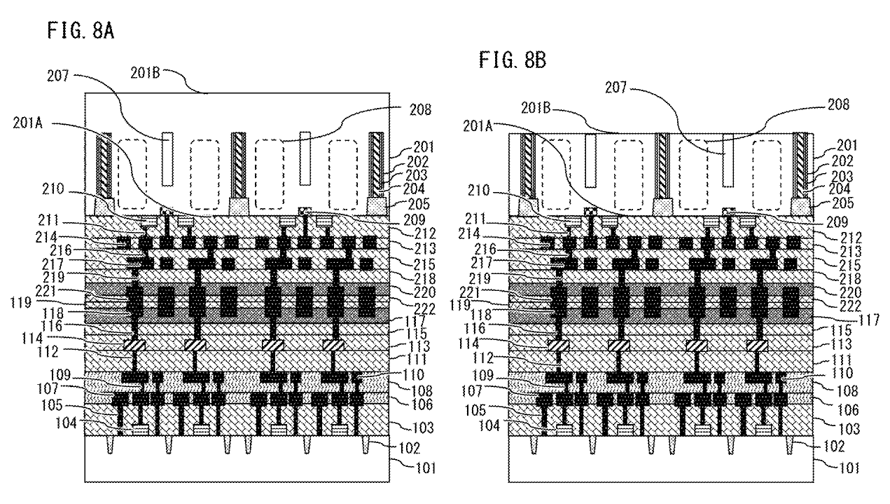

Then, as shown in FIG. 8A, the circuit substrate 10 and the PD substrate 20 manufactured by the above method are bonded using hybrid bonding such that the first bonding electrode 118 and the second bonding electrode 221 overlap in a plan view. Thereafter, as shown in FIG. 8B, the second main surface 201B side of the second semiconductor substrate 201 is thinned. In the present embodiment, the second semiconductor substrate 201 is thinned such that an end portion on the second main surface 201B side of the inter-pixel trench 204 is exposed at the surface. However, the second semiconductor substrate 201 may be thinned such that the end portion on the second main surface 201B side of the inter-pixel trench 204 is not exposed at the surface.

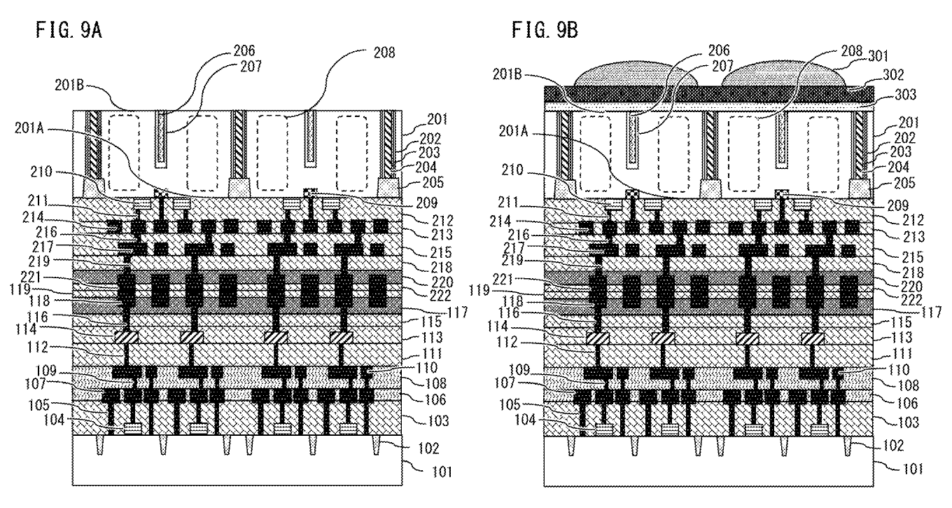

Next, as shown in FIG. 9A, from the second main surface 201B side of the second semiconductor substrate 201, inter-PD trenches 206 are formed. Here, as shown in FIG. 9A, the inter-PD trench 206 is formed so as to be covered by the first P-type diffusion layer 207. The inter-PD trench 206 may be formed of a silicon oxide film. In the present embodiment, in a plan view, the inter-PD trench 206 and the inter-pixel trench 204 have portions that intersect each other. Therefore, in a portion where the inter-PD trench 206 and the inter-pixel trench 204 intersect each other, when grooves of the inter-PD trench 206 are formed, an end portion on the second main surface 201B side of the inter-pixel trench 204 is etched.

Next, on the second main surface 201B side of the second semiconductor substrate 201, a back surface interlayer film 303 is formed. As the back surface interlayer film 303, for example, a silicon oxide film or a silicon nitride film may be adopted. Between the back surface interlayer film 303 and an end portion of the second main surface 201B of the second semiconductor substrate 201, an antireflection film (not shown) made of tantalum oxide or the like may be formed. Further, inside of the back surface interlayer film 303, optical elements (not shown) such as an in-layer lens and a light-shielding wall may be arranged.

Then, as shown in FIG. 9B, after a color filter layer 302 and a microlens 301 are arranged on the back surface interlayer film 303, a pad opening (not shown) is formed such that at least a part of the first upper-layer wiring 114 is exposed. By the above, the photoelectric conversion device 1 according to the present embodiment is manufactured.

Therefore, according to the photoelectric conversion device 1 according to the present embodiment, a trench structure capable of achieving both suppression of deterioration of crosstalk and suppression of a decrease in linearity of signal intensity is realized.

In the photoelectric conversion device 1 according to the present embodiment, each pixel unit is configured such that two pixels share one microlens, but the pixels constituting each pixel unit are not limited to two. That is, it is sufficient that the pixel unit is configured such that a microlens and pixels correspond in a one-to-many relationship. Further, as shown in FIG. 2, the number of pixels arranged for each pixel unit may be the same, or the number of pixels arranged for each pixel unit may be different. This can also be applied to modification examples and embodiments explained below.

### First Modified Example

Next, a first modified example, which is a modification example of the photoelectric conversion device 1 according to the present embodiment, will be explained. Incidentally, in the following description, the same configurations as those of the embodiments are given the same reference numerals and signs, and detailed description thereof will be omitted.

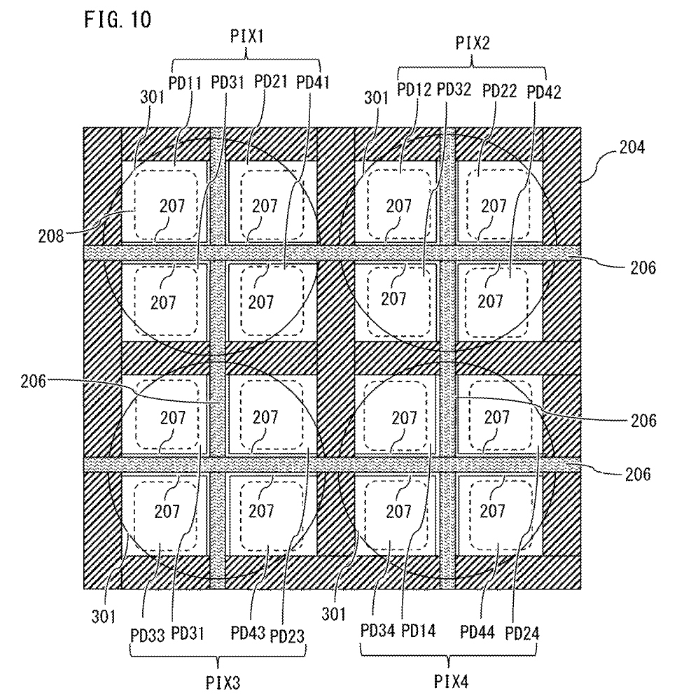

FIG. 10 shows a configuration of pixel units in a plan view of a part of the light-receiving pixel region 11 of the photoelectric conversion device 1 according to the present modification example. In FIG. 10, pixel units PIX1 to PIX4 arranged in 2 rows and 2 columns in a plan view are shown. As shown in FIG. 10, in the pixel unit PIX1, four photodiodes PD11, PD21, PD31, and PD41 are arranged. A microlens 301 for efficiently focusing incident light onto the photodiodes PD11, PD21, PD31, and PD41 is arranged on the photodiodes PD11, PD21, PD31, and PD41. In the present embodiment, the photodiodes PD11, PD21, PD31, and PD41 are configured to share one microlens 301. The pixel units PIX2 to PIX4 also include photodiodes PD12, PD22, PD32, and PD42, photodiodes PD13, PD23, PD33, and PD43, and photodiodes PD14, PD24, PD34, and PD44, respectively. In addition, the pixel units PIX2 to PIX4 also have a configuration similar to PIX1.

Further, between the pixel unit PIX1 and the pixel unit PIX2 that are adjacent to each other in a plan view, between the pixel unit PIX1 and the pixel unit PIX3, between the pixel unit PIX2 and the pixel unit PIX4, and between the pixel unit PIX3 and the pixel unit PIX4, inter-pixel trenches 204 are formed. By the inter-pixel trenches 204, crosstalk between pixel units adjacent across the inter-pixel trench 204 is suppressed. Further, in the pixel unit PIX1, between the photodiodes PD11 and PD21, an inter-PD trench 206 for preventing crosstalk between PDs is formed. Similarly, between the photodiodes PD11 and PD31, between the photodiodes PD21 and PD41, and between the photodiodes PD31 and PD41, inter-PD trenches 206 are formed, respectively. In the pixel units PIX2 to PIX4 as well, similar inter-PD trenches 206 are formed. Further, the inter-PD trenches 206 are formed so as to cross the inter-pixel trenches 204.

Therefore, according to the photoelectric conversion device 1 according to the present modification example, similarly to the first embodiment, in the pixel units PIX1 to PIX4, crosstalk between respective photodiodes constituting the pixel units is suitably suppressed, respectively. Further, according to the photoelectric conversion device 1 according to the present modification example, similarly to the first embodiment, leak paths are formed at lower portions of the inter-PD trenches 206. Thereby, dark electrons generated from sidewall portions of the inter-pixel trenches 204 become difficult to mix with signal charges, and an effect of suppressing a decrease in linearity of signal intensity of an output signal can also be expected.

### Second Embodiment

Next, a photoelectric conversion device according to a second embodiment will be explained. In addition, in the following explanation, the same reference numerals are assigned to configurations similar to the photoelectric conversion device 1 according to the first embodiment, and detailed explanations are omitted.

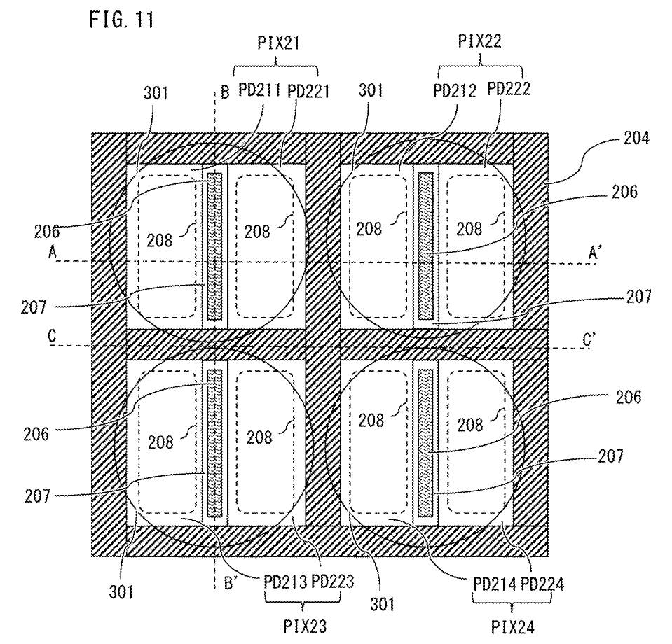

FIG. 11 shows a plan view when the light-receiving pixel region 11 of the photoelectric conversion device 1 in the present embodiment is viewed from the incident light side. In FIG. 11, pixel units PIX21 to PIX24 arranged in 2 rows and 2 columns in a plan view are shown. In the pixel unit PIX21, photodiodes PD211 and PD221 are arranged. A microlens 301 for efficiently focusing incident light onto the photodiodes PD211 and PD221 is arranged on the photodiodes PD211 and PD221. In the present embodiment, the photodiodes PD211 and PD221 are configured to share one microlens 301. The pixel units PIX22 to PIX24 also include photodiodes PD212 and PD222, photodiodes PD213 and PD223, and photodiodes PD214 and PD224, respectively, and have a configuration similar to PIX21.

Between the pixel unit PIX21 and the pixel unit PIX22 that are adjacent to each other in a plan view, between the pixel unit PIX21 and the pixel unit PIX23, between the pixel unit PIX22 and the pixel unit PIX24, and between the pixel unit PIX23 and the pixel unit PIX24, inter-pixel trenches 204 are formed. By the inter-pixel trenches 204, crosstalk between pixel units adjacent across the inter-pixel trench 204 is suppressed. Further, in the pixel unit PIX21, between the photodiodes PD211 and PD221, an inter-PD trench 206 for preventing crosstalk between PDs is formed. Similarly, in the pixel units PIX22 to PIX24 as well, inter-PD trenches 206 are formed.

As shown in FIG. 11, in the present embodiment, end portions in a plan view of the inter-PD trenches 206 are arranged so as to be separated from the inter-pixel trenches 204. Therefore, in a plan view of the substrate, the inter-pixel trench 204 and the inter-PD trench 206 do not have portions that intersect each other. Further, in a plan view of the substrate, between the inter-pixel trench 204 and the inter-PD trench 206, a first P-type diffusion layer 207 is arranged. Thereby, crosstalk between photodiodes due to a gap generated between the inter-PD trench 206 and the inter-pixel trench 204 can be suppressed by the first P-type diffusion layer 207. Further, the first P-type diffusion layer 207 is also arranged on a sidewall portion of the inter-PD trench 206.

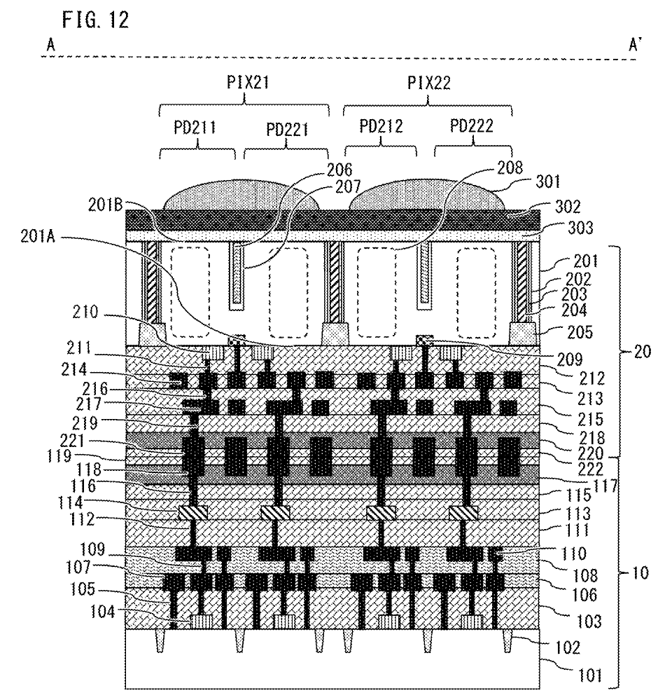

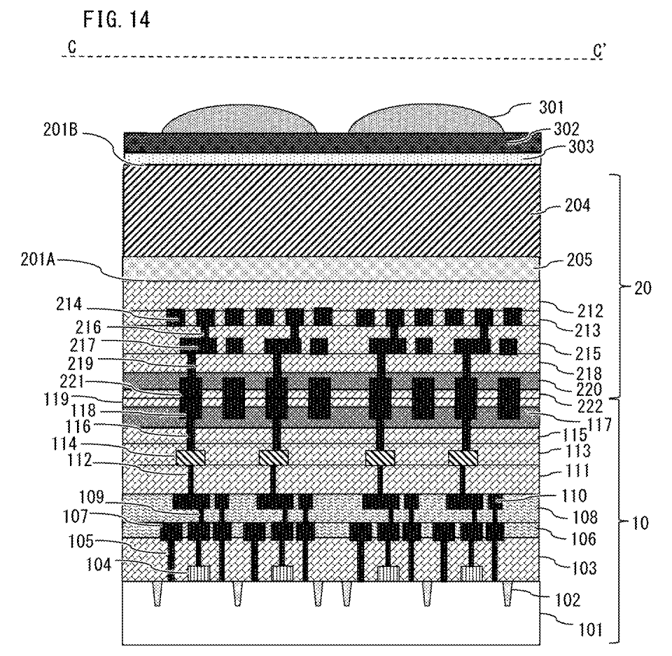

FIGS. 12, 13, and 14 show cross-sectional views of the photoelectric conversion device 1 taken along line A-A', line B-B', and line C-C' of FIG. 11, respectively. FIGS. 12 to 14 correspond to the cross-sectional views of FIGS. 3 to 5, respectively. Regarding the configuration of the photoelectric conversion device 1 according to the present embodiment shown in FIGS. 12 to 14, points different from the configuration of the photoelectric conversion device 1 in the first embodiment will be explained.

In the present embodiment, unlike the first embodiment, since the inter-pixel trench 204 and the inter-PD trench 206 are configured so as not to have portions that intersect each other, the inter-pixel trench 204 is not etched during formation of the inter-PD trench 206. Therefore, stable trench formation becomes possible.

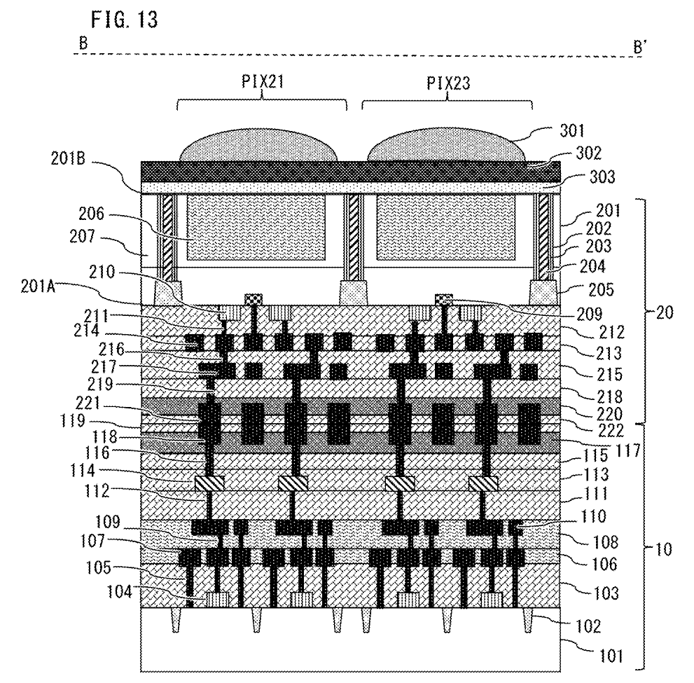

Further, as shown in FIG. 13, between the pixel unit PIX21 and the pixel unit PIX23, an inter-pixel trench 204 is formed. Further, in the cross-section of FIG. 13, an end portion on the second main surface 201B side of the inter-pixel trench 204 is arranged so as to be in contact with the second main surface 201B side, similarly to the inter-pixel trench 204 shown in the cross-section of FIG. 12. Therefore, by the inter-pixel trench 204, crosstalk between pixel units adjacent across the inter-pixel trench 204 is suppressed.

Therefore, according to the photoelectric conversion device 1 according to the present embodiment, similarly to the first embodiment, crosstalk between respective pixel units and crosstalk between respective photodiodes constituting a pixel unit are suitably suppressed. Further, according to the photoelectric conversion device 1 according to the present embodiment, similarly to the first embodiment, leak paths are formed at lower portions of the inter-PD trenches 206. Thereby, dark electrons generated from sidewall portions of the inter-pixel trenches 204 become difficult to mix with signal charges, and an effect of suppressing a decrease in linearity of signal intensity of an output signal can also be expected.

### Second Modified Example

Next, a second modified example, which is a modification example of the photoelectric conversion device 1 according to the second embodiment, will be explained. Incidentally, in the following description, the same configurations as those of the embodiments are given the same reference numerals and signs, and detailed description thereof will be omitted.

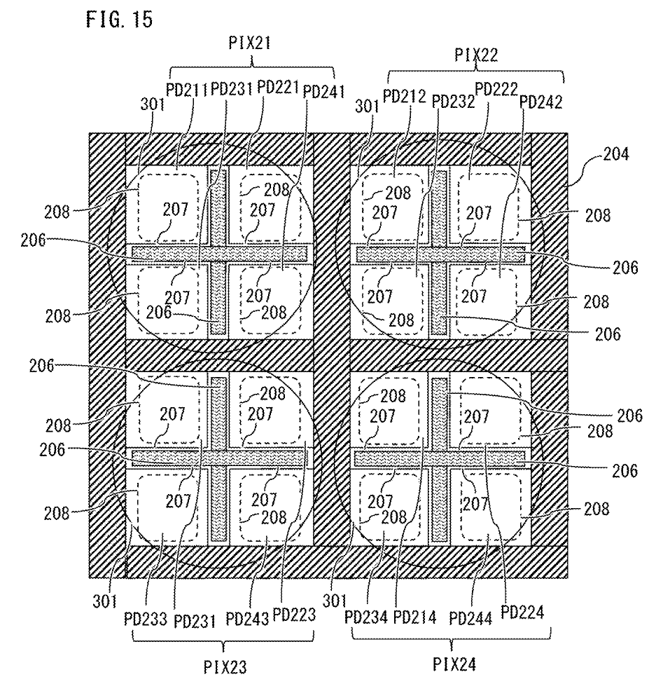

FIG. 15 shows a configuration of pixel units in a plan view of a part of the light-receiving pixel region 11 of the photoelectric conversion device 1 according to the present modification example. In FIG. 15, pixel units PIX21 to PIX24 arranged in 2 rows and 2 columns in a plan view are shown. As shown in FIG. 15, in the pixel unit PIX21, four photodiodes PD211, PD221, PD231, and PD241 are arranged. Further, the photodiodes PD211, PD221, PD231, and PD241 are configured to share one microlens 301. The pixel units PIX22 to PIX24 also include photodiodes PD212, PD222, PD232, and PD242, photodiodes PD213, PD223, PD233, and PD243, and photodiodes PD214, PD224, PD234, and PD244, respectively. In addition, the pixel units PIX22 to PIX24 also have a configuration similar to PIX21.

Further, between the pixel unit PIX21 and the pixel unit PIX22 that are adjacent to each other in a plan view, between the pixel unit PIX21 and the pixel unit PIX23, between the pixel unit PIX22 and the pixel unit PIX24, and between the pixel unit PIX23 and the pixel unit PIX24, inter-pixel trenches 204 are formed. By the inter-pixel trenches 204, crosstalk between pixel units adjacent across the inter-pixel trench 204 is suppressed. Further, in the pixel unit PIX21, between the photodiodes PD211 and PD221, an inter-PD trench 206 for preventing crosstalk between PDs is formed. Similarly, between the photodiodes PD211 and PD231, between the photodiodes PD221 and PD241, and between the photodiodes PD231 and PD241, inter-PD trenches 206 are formed, respectively. In the pixel units PIX22 to PIX24 as well, similar inter-PD trenches 206 are formed. Further, end portions in a plan view of the inter-PD trenches 206 are arranged so as to be separated from the inter-pixel trenches 204, and between the inter-pixel trench 204 and the inter-PD trench 206, a first P-type diffusion layer 207 is arranged.

Therefore, according to the photoelectric conversion device 1 according to the present modification example, similarly to the second embodiment, crosstalk between respective pixel units and crosstalk between respective photodiodes constituting a pixel unit are suitably suppressed. Further, according to the photoelectric conversion device 1 according to the present modification example, similarly to the second embodiment, leak paths are formed at lower portions of the inter-PD trenches 206. Thereby, dark electrons generated from sidewall portions of the inter-pixel trenches 204 become difficult to mix with signal charges, and an effect of suppressing a decrease in linearity of signal intensity of an output signal can also be expected.

### Third Embodiment

Next, a photoelectric conversion device according to a third embodiment will be explained. In addition, in the following explanation, the same reference numerals are assigned to configurations similar to the photoelectric conversion device 1 according to the first to second embodiments, and detailed explanations are omitted.

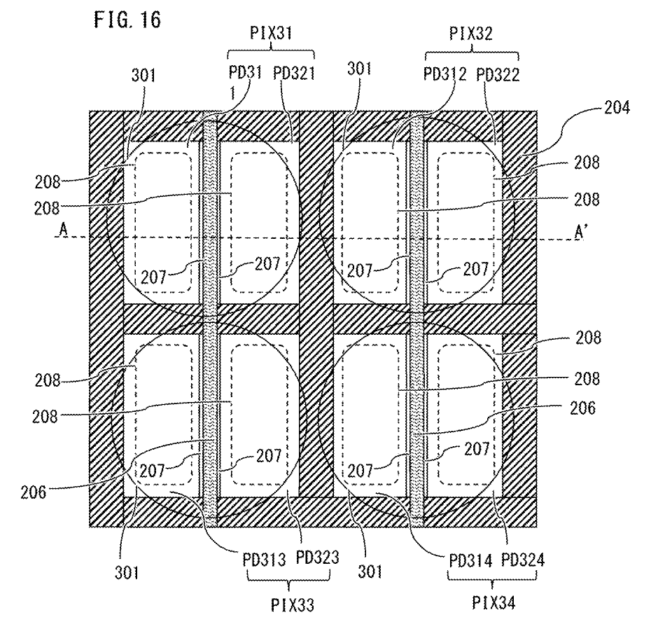

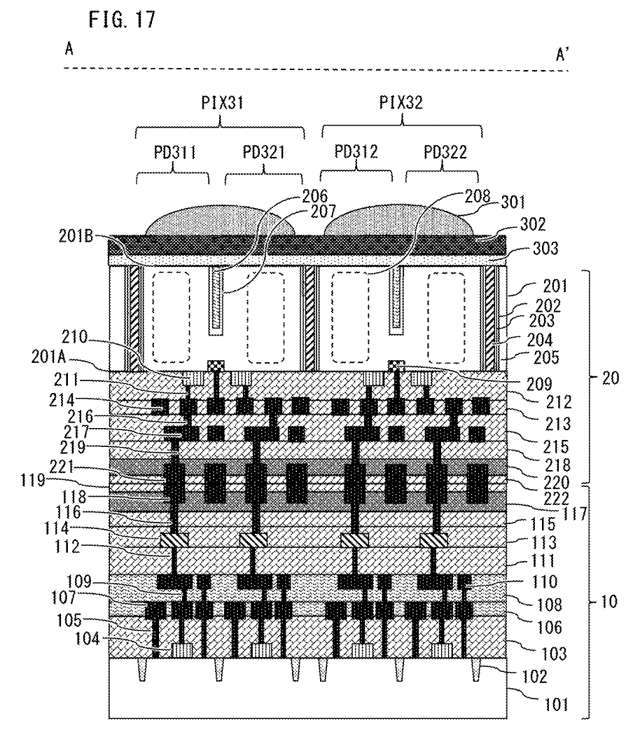

FIG. 16 shows a configuration of pixel units in a plan view of a part of the light-receiving pixel region 11 of the photoelectric conversion device 1 according to the present embodiment. In FIG. 16, pixel units PIX31 to PIX34 arranged in 2 rows and 2 columns in a plan view are shown. FIG. 17 shows a cross-sectional view of the photoelectric conversion device 1 taken along line A-A' of FIG. 16. The photoelectric conversion device 1 according to the present embodiment has a configuration similar to the photoelectric conversion device 1 according to the first embodiment. In the following explanation, points different from the configuration of the photoelectric conversion device 1 according to the first embodiment will be explained.

As shown in FIG. 16, in the pixel unit PIX31, two photodiodes PD311 and PD321 are arranged. Further, the photodiodes PD311 and PD321 are configured to share one microlens 301. The pixel units PIX32 to PIX34 also include photodiodes PD312 and PD322, photodiodes PD313 and PD323, and photodiodes PD314 and PD324, respectively. In addition, the pixel units PIX32 to PIX34 also have a configuration similar to PIX31.

As shown in FIG. 17, in the photoelectric conversion device 1 according to the present embodiment, unlike the first embodiment, a second element isolation portion 205 is not provided at an end portion on the first main surface 201A side of the inter-pixel trench 204. Further, the inter-pixel trench 204 penetrates the second semiconductor substrate 201, and respective end portions of the inter-pixel trench 204 are in contact with the first main surface 201A and the second main surface 201B, respectively. By the configuration of the inter-pixel trench 204 of the present embodiment, it becomes possible to further simplify a manufacturing process of the photoelectric conversion device 1 compared to the first embodiment.

Further, according to the photoelectric conversion device 1 according to the present embodiment, similarly to the first embodiment, crosstalk between respective pixel units and crosstalk between respective photodiodes constituting a pixel unit are suitably suppressed. Further, according to the photoelectric conversion device 1 according to the present embodiment, similarly to the first embodiment, leak paths are formed at lower portions of the inter-PD trenches 206. Thereby, dark electrons generated from sidewall portions of the inter-pixel trenches 204 become difficult to mix with signal charges, and an effect of suppressing a decrease in linearity of signal intensity of an output signal can also be expected.

### Fourth Embodiment

Next, a photoelectric conversion device according to a fourth embodiment will be explained. In addition, in the following explanation, the same reference numerals are assigned to configurations similar to the photoelectric conversion device 1 according to the first to third embodiments, and detailed explanations are omitted.

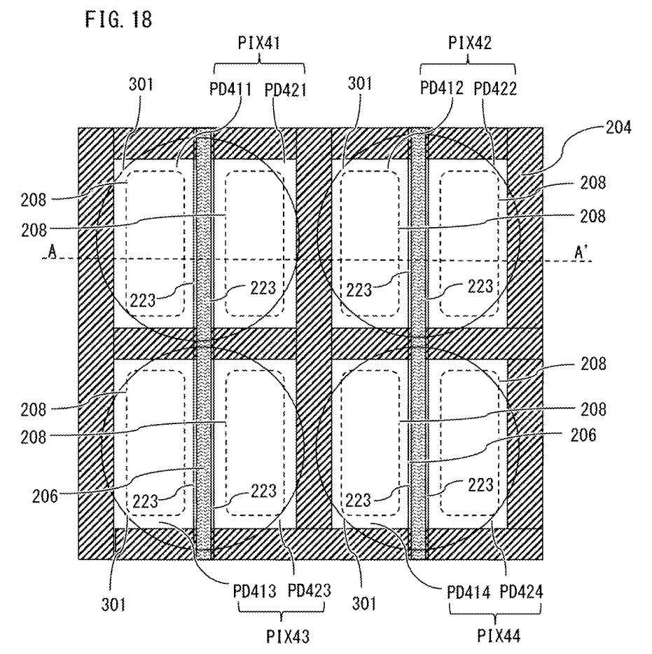

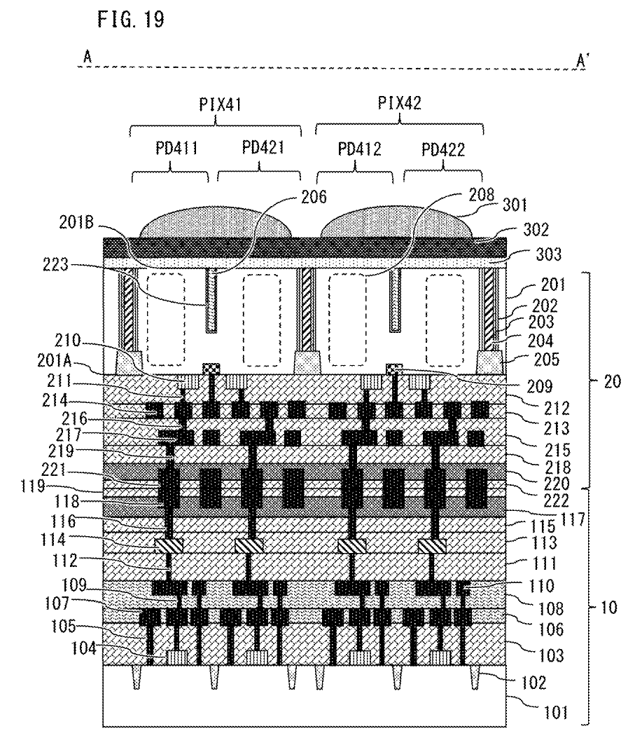

FIG. 18 shows a configuration of pixel units in a plan view of a part of the light-receiving pixel region 11 of the photoelectric conversion device 1 according to the present embodiment. In FIG. 18, pixel units PIX41 to PIX44 arranged in 2 rows and 2 columns in a plan view are shown. FIG. 19 shows a cross-sectional view of the photoelectric conversion device 1 taken along line A-A' of FIG. 18. The photoelectric conversion device 1 according to the present embodiment has a configuration similar to the photoelectric conversion device 1 according to the first embodiment. In the following explanation, points different from the configuration of the photoelectric conversion device 1 according to the first embodiment will be explained.

As shown in FIG. 18, in the pixel unit PIX41, two photodiodes PD411 and PD421 are arranged. Further, the photodiodes PD411 and PD421 are configured to share one microlens 301. The pixel units PIX42 to PIX44 also include photodiodes PD412 and PD422, photodiodes PD413 and PD423, and photodiodes PD414 and PD424, respectively. In addition, the pixel units PIX42 to PIX44 also have a configuration similar to PIX41.

As shown in FIGS. 18 and 19, in the photoelectric conversion device 1 according to the present embodiment, instead of the first P-type diffusion layer 207, a high-dielectric film 223, which is a film that retains fixed charges, is formed on a sidewall portion of the inter-PD trench 206. As the high-dielectric film 223, hafnium oxide or aluminum oxide may be adopted. In the present embodiment, by fixed charges of the high-dielectric film 223 that covers at least a part of the inter-PD trench 206, a P-type diffusion layer can be formed in a self-aligned manner on a sidewall portion of the inter-PD trench 206. Therefore, it becomes possible to form a charge storage portion 208 to a position closer to the inter-PD trench 206 compared to the first embodiment. As a result, it can be expected that a dynamic range is further improved in the photoelectric conversion device 1.

### Fifth Embodiment

Next, a photoelectric conversion device according to a fifth embodiment will be explained. In addition, in the following explanation, the same reference numerals are assigned to configurations similar to the photoelectric conversion device 1 according to the first to fourth embodiments, and detailed explanations are omitted.

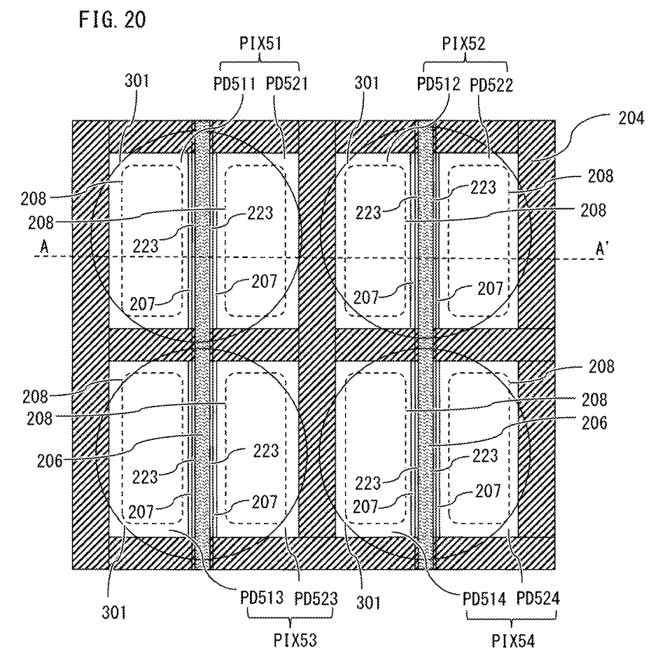

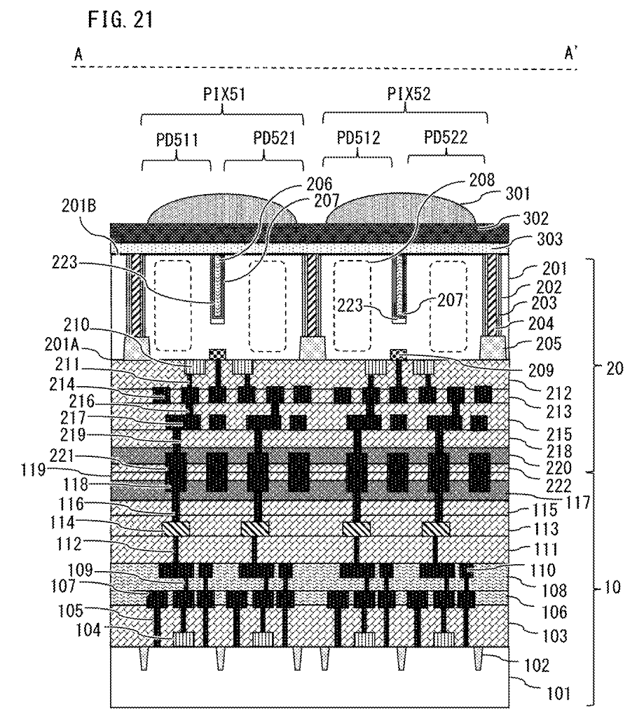

FIG. 20 shows a configuration of pixel units in a plan view of a part of the light-receiving pixel region 11 of the photoelectric conversion device 1 according to the present embodiment. In FIG. 20, pixel units PIX51 to PIX54 arranged in 2 rows and 2 columns in a plan view are shown. FIG. 21 shows a cross-sectional view of the photoelectric conversion device 1 taken along line A-A' of FIG. 20. The photoelectric conversion device 1 according to the present embodiment has a configuration similar to the photoelectric conversion device 1 according to the first embodiment. In the following explanation, points different from the configuration of the photoelectric conversion device 1 according to the first embodiment will be explained.

As shown in FIG. 20, in the pixel unit PIX51, two photodiodes PD511 and PD521 are arranged. Further, the photodiodes PD511 and PD521 are configured to share one microlens 301. The pixel units PIX52 to PIX54 also include photodiodes PD512 and PD522, photodiodes PD513 and PD523, and photodiodes PD514 and PD524, respectively. In addition, the pixel units PIX52 to PIX54 also have a configuration similar to PIX51.

As shown in FIGS. 20 and 21, in the photoelectric conversion device 1 according to the present embodiment, on a sidewall portion of the inter-PD trench 206, a first P-type diffusion layer 207 and a high-dielectric film 223 are formed so as to be stacked. In the present embodiment, the first P-type diffusion layer 207 is formed so as to cover the inter-PD trench 206, and the high-dielectric film 223 is formed so as to cover the first P-type diffusion layer 207. Thereby, a hole concentration at a sidewall portion of the inter-PD trench 206 can be made higher compared to the photoelectric conversion device 1 according to the first embodiment. As a result, in the photoelectric conversion device 1, it can be expected that generation of dark electrons is more effectively suppressed.

### Sixth Embodiment

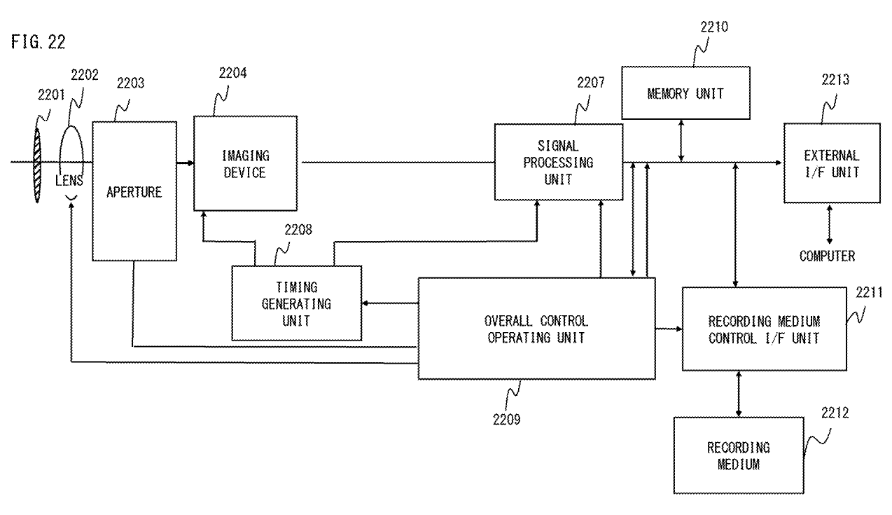

A photoelectric conversion system according to the present embodiment will be described with reference to FIG. 22. FIG. 22 is a block diagram showing a schematic configuration of the photoelectric conversion system according to the present embodiment.

The photoelectric conversion devices described in the first to fifth embodiments can be applied to various photoelectric conversion systems. Each of the photoelectric conversion systems includes at least the photoelectric conversion devices according to any of the embodiments described above and a signal processing unit that processes signals output from the photoelectric conversion device. Examples of devices to which such a photoelectric conversion system can be applied include a digital still camera, a digital camcorder, a monitoring camera, a copier, a facsimile, a mobile phone, a vehicle-mounted camera, an observation satellite, a sensor, and a measuring instrument. In addition, camera modules provided with an optical system such as a lens and an imaging device are also included in devices to which a photoelectric conversion system is applied. FIG. 22 illustrates a block diagram of a digital still camera as an example of such devices.

The photoelectric conversion system illustrated in FIG. 22 has an imaging device 2204 as an example of the photoelectric conversion device and a lens 2202 that causes an optical image of an object to be formed on the imaging device 2204. In addition, the photoelectric conversion system has an aperture 2203 for making a light amount that passes through the lens 2202 variable and a barrier 2201 for protecting the lens 2202. The lens 2202 and the aperture 2203 optical systems for collecting light to the imaging device 2204. The imaging device 2204 is the photoelectric conversion device (imaging device) according to any of the embodiments described above and converts an optical image having been formed by the lens 2202 into an electric signal.

The photoelectric conversion system also has a signal processing unit 2207 which is an image generating unit for generating an image by processing an output signal that is output from the imaging device 2204. The signal processing unit 2207 performs operations in which the output signal is subjected to various corrections and compression when necessary and image data is output. The signal processing unit 2207 may be formed on a semiconductor substrate provided with the imaging device 2204 or formed on a semiconductor substrate that is separate from the imaging device 2204. In addition, the imaging device 2204 and the signal processing unit 2207 may be formed on a same semiconductor substrate.

The photoelectric conversion system further has a memory unit 2210 for temporarily storing image data and an external interface unit (an external I/F unit) 2213 for communicating with an external computer or the like. Furthermore, the photoelectric conversion system has a recording medium 2212 such as a semiconductor memory for recording or reading imaging data and a recording medium control interface unit (a recording medium control I/F unit) 2211 for performing recording or reading with respect to the recording medium 2212. The recording medium 2212 may be built into the photoelectric conversion system or may be attachable to and detachable from the photoelectric conversion system.

Furthermore, the photoelectric conversion system has an overall control operating unit 2209 that performs various arithmetic operations and controls the entire digital still camera and a timing generating unit 2208 that outputs various timing signals to the imaging device 2204 and the signal processing unit 2207. In this case, the timing signals and the like may be input from outside and the photoelectric conversion system need at least have the imaging device 2204 and the signal processing unit 2207 that processes an output signal that is output from the imaging device 2204.

The imaging device 2204 outputs an imaging signal to the signal processing unit 2207. The signal processing unit 2207 performs predetermined signal processing on the imaging signal output from the imaging device 2204 and outputs image data. The signal processing unit 2207 generates an image using the imaging signal.

As described above, according to the present embodiment, a photoelectric conversion system to which the photoelectric conversion device (imaging device) according to any of the embodiments described above is applied can be realized.

### Seventh Embodiment

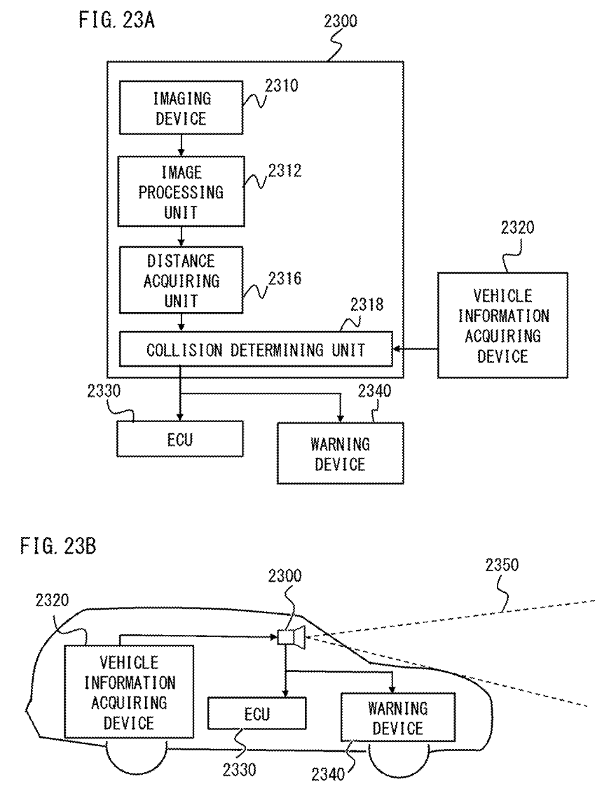

A photoelectric conversion system and a moving body according to the present embodiment will be described with reference to FIGS. 23A and 23B. FIG. 23A is a diagram showing a configuration of the photoelectric conversion system according to the present embodiment and FIG. 23B is a diagram showing a configuration of the moving body according to the present embodiment.

FIG. 23A shows an example of a photoelectric conversion system related to a vehicle-mounted camera. A photoelectric conversion system 2300 includes an imaging device 2310 to which the photoelectric conversion device (imaging device) described in any one of the embodiments described above is applied. The photoelectric conversion system 2300 has an image processing unit 2312 that performs image processing on a plurality of pieces of image data acquired by the imaging device 2310. In addition, the photoelectric conversion system 2300 has a distance acquiring unit 2316 that calculates a distance to an object and a collision determining unit 2318 that determines whether or not there is a possibility of a collision based on the calculated distance. In this case, the distance acquiring unit 2316 may acquire information on the distance to the object based on a ToF (Time of Flight) or may acquire distance information using parallax information or the like. Furthermore, the distance acquiring unit 2316 may acquire distance information by combining ranging according to ToF and ranging based on a phase difference between pixels. In other words, distance information is information related to a parallax, a defocus amount, a distance to the object, or the like. The collision determining unit 2318 may determine a possibility of a collision using any of these pieces of distance information. The distance information acquiring means may be realized by exclusively-designed hardware or may be realized by a software module. Alternatively, the distance information acquiring means may be realized by an FPGA (Field Programmable Gate Array), an ASIC (Application Specific Integrated Circuit), or the like, or a combination thereof.

The photoelectric conversion system 2300 is connected to a vehicle information acquiring device 2320 and is capable of acquiring vehicle information such as a vehicle speed, a yaw rate, and a steering angle. In addition, an ECU 2330 which is a control device that outputs a control signal causing a vehicle to generate a braking force based on a determination result of the collision determining unit 2318 is connected to the photoelectric conversion system 2300. Furthermore, the photoelectric conversion system 2300 is also connected to a warning device 2340 that issues a warning to a driver based on a determination result of the collision determining unit 2318. For example, when it is found that the possibility of a collision is high as a determination result of the collision determining unit 2318, the ECU 2330 performs vehicle control involving applying the brakes, releasing the gas pedal, suppressing engine output, or the like to avoid a collision and/or reduce damage. The warning device 2340 issues a warning to a user by sounding an alarm, displaying warning information on a screen of a car navigation system or the like, vibrating a seat belt or a steering wheel, or the like.

In the present embodiment, an image of a periphery of the vehicle such as the front or the rear of the vehicle is picked up by the photoelectric conversion system 2300. FIG. 23B shows the photoelectric conversion system when imaging of the front of the vehicle (an imaging range 2350) is performed. The vehicle information acquiring device 2320 sends an instruction to the photoelectric conversion system 2300 or the imaging device 2310. According to such a configuration, accuracy of ranging can be further improved.

While an example of controlling a vehicle so as to prevent a collision with another vehicle has been described above, the photoelectric conversion system can also be applied to controlling automated driving so that the vehicle follows another vehicle, controlling automated driving so that the vehicle stays within a lane, and the like. In addition, the photoelectric conversion system is not limited to a vehicle such as an automobile and can also be applied to a moving body (moving device) such as a ship, an airplane, or an industrial robot. The moving body includes one of or both of a driving force generating unit that generates a driving force mainly used for movement of the moving body and a rotating member that is mainly used for movement of the moving body. The driving force generating unit can be an engine, a motor, or the like. The rotating member can be a tire, a wheel, a screw of a ship, a propeller of a flight vehicle, or the like. Moreover, besides moving bodies, the photoelectric conversion system can be applied to a wide variety of devices that utilize object recognition such as an intelligent transportation system (ITS).

### Eighth Embodiment

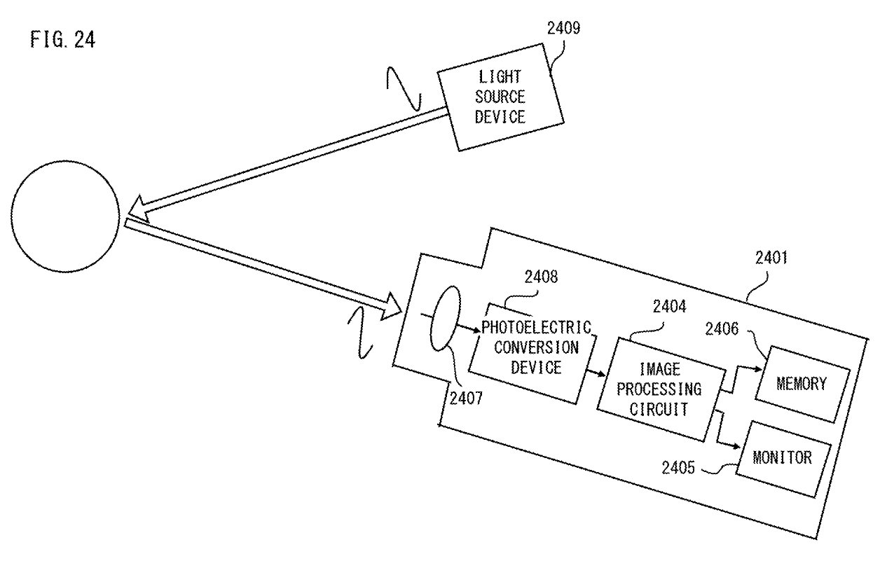

A photoelectric conversion system according to the present embodiment will be described with reference to FIG. 24. FIG. 24 is a block diagram showing a configuration example of a distance image sensor that is the photoelectric conversion system according to the present embodiment.

As shown in FIG. 24, a distance image sensor 2401 is configured to include an optical system 2407, a photoelectric conversion device 2408, an image processing circuit 2404, a monitor 2405, and a memory 2406. In addition, the distance image sensor 2401 is capable of acquiring a distance image in accordance with a distance to a subject by receiving light (modulated light or pulsed light) emitted toward the subject from a light source device 2409 and reflected by a surface of the subject.

The optical system 2407 is configured with one or a plurality of lenses and guides image light (incident light) from the subject to the photoelectric conversion device 2408 and forms an image on a light-receiving surface (a sensor unit) of the photoelectric conversion device 2408.

The image processing circuit 2404 performs image processing for constructing a distance image based on the distance signal supplied from the photoelectric conversion device 2408. In addition, a distance image (image data) obtained by the image processing is supplied to and displayed by the monitor 2405 or supplied to and stored (recorded) in the memory 2406.

With the distance image sensor 2401 configured as described above, applying one of the photoelectric conversion devices described above enables, for example, a more accurate distance image to be acquired due to an improvement in ranging accuracy.

### Ninth Embodiment

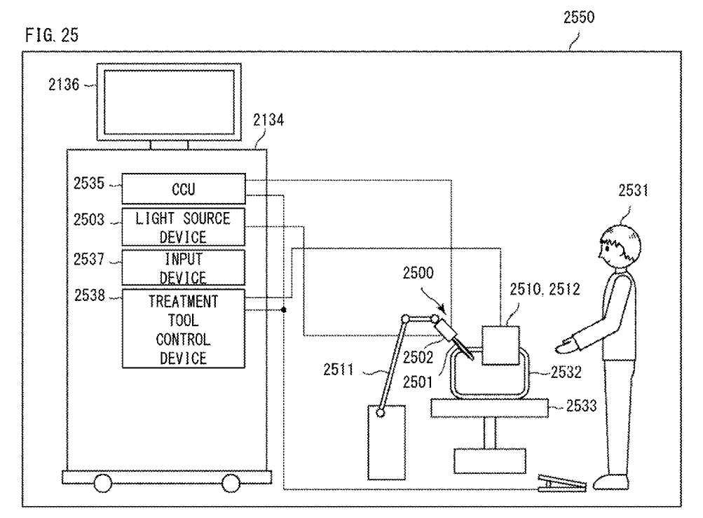

A photoelectric conversion system according to the present embodiment will be described with reference to FIG. 25. FIG. 25 is a diagram showing an example of a schematic configuration of an endoscopic surgery system that is the photoelectric conversion system according to the present embodiment.

FIG. 25 illustrates a situation where a technician (a physician) 2531 is using an endoscopic surgery system 2550 to operate on a patient 2532 on a patient bed 2533. As illustrated, the endoscopic surgery system 2550 is constituted of an endoscope 2500, a surgical instrument 2510, and a cart 2534 mounted with various devices for an endoscopic surgery.

The endoscope 2500 is constituted of a lens barrel 2501 of which a region with a predetermined length from a distal end is to be inserted into a body cavity of the patient 2532 and a camera head 2502 connected to a base end of the lens barrel 2501. While the illustrated example features the endoscope 2500 being configured as a so-called rigid scope having a rigid lens barrel 2501, alternatively, the endoscope 2500 may be configured as a so-called flexible scope having a flexible lens barrel.

An opening into which an objective lens is fitted is provided at the distal end of the lens barrel 2501. A light source device 2503 is connected to the endoscope 2500, and light generated by the light source device 2503 is guided to the distal end of the lens barrel 2501 by a light guide provided so as to extend inside the lens barrel and emitted toward an observation object inside a body cavity of the patient 2532 via the objective lens. It should be noted that the endoscope 2500 may be a forward-viewing endoscope, an oblique-viewing endoscope, or a side-viewing endoscope.

An optical system and a photoelectric conversion device are provided inside the camera head 2502 and reflected light (observation light) from the observation object is collected to the photoelectric conversion device by the optical system. The observation light is photoelectrically converted by the photoelectric conversion device and an electric signal corresponding to the observation light or, in other words, an image signal corresponding to an observed image is generated. As the photoelectric conversion device, the photoelectric conversion device according to any one of the embodiments described above can be used. The image signal is transmitted to a Camera Control Unit (CCU) 2535 as RAW data.

The CCU 2535 is constituted of a CPU (Central Processing Unit), a GPU (Graphics Processing Unit), or the like and comprehensively controls operations of the endoscope 2500 and a display device 2536. In addition, the CCU 2535 receives an image signal from the camera head 2502 and subjects the image signal to various kinds of image processing for displaying an image based on the image signal such as development processing (demosaicing).

Under control exerted by the CCU 2535, the display device 2536 displays an image based on the image signal subjected to image processing by the CCU 2535. The light source device 2503 is constituted of a light source such as an LED (Light-Emitting Diode) and supplies the endoscope 2500 with irradiation light used when photographing a surgical site or the like.

An input device 2537 is an input interface with respect to the endoscopic surgery system 2550. A user can input various kinds of information and input instructions to the endoscopic surgery system 2550 via the input device 2537.

A treatment tool control device 2538 controls drive of an energy treatment tool 2512 for cauterizing or incising tissue, sealing a blood vessel, or the like. The light source device 2503 that supplies the endoscope 2500 with irradiation light when photographing a surgical site can be constituted of a white light source constituted of an LED, a laser light source, or a combination thereof. When the white light source is constituted of a combination of RGB laser light sources, since output intensity and an output timing of each color (each wavelength) can be controlled with high accuracy, white balance of a captured image can be adjusted in the light source device 2503. In addition, in this case, an image corresponding to each of RGB can be captured in a time-divided manner by having an observation object be irradiated with laser light from each of the RGB laser light sources in a time-divided manner and controlling drive of an imaging element of the camera head 2502 in synchronization with the irradiation timing. According to this method, a color image can be obtained without having to provide the imaging element with a color filter.

In addition, drive of the light source device 2503 may be controlled such that intensity of output light changes at predetermined intervals. By controlling drive of imaging elements of the camera head 2502 in synchronization with a timing at which the intensity of light changes to acquire images in a time-divided manner and compositing the images, an image with a high dynamic range that is free of so-called blocked-up shadows and blown-out highlights can be generated.

Furthermore, the light source device 2503 may be configured to be capable of supplying light in a predetermined wavelength band that accommodates special light observation. In special light observation, for example, wavelength dependence of absorption of light by body tissue is utilized. Specifically, predetermined tissue such as a blood vessel of a superficial portion of a mucous membrane is photographed with high contrast by irradiating light with a narrower band than irradiation light during normal observation (in other words, white light). Alternatively, in special light observation, fluorescent observation may be performed in which an image is obtained using fluorescent light generated by irradiating excitation light. In fluorescent observation, body tissue may be irradiated with excitation light and fluorescent light from the body tissue can be observed, a reagent such as indocyanine green (ICG) can be locally injected into body tissue and the body tissue can be irradiated with excitation light corresponding to a fluorescent wavelength of the reagent to obtain a fluorescent image, and the like. The light source device 2503 may be configured to be capable of supplying narrow-band light and/or excitation light that accommodates such special light observation.

### Tenth Embodiment

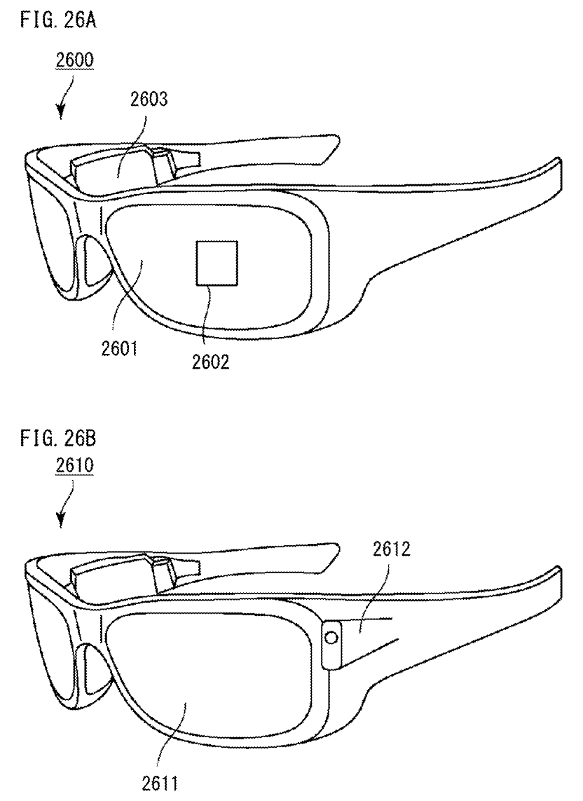

A photoelectric conversion system according to the present embodiment will be described with reference to FIGS. 26A and 26B. FIG. 26A illustrates eyeglasses 2600 (smart glasses) that is the photoelectric conversion system according to the present embodiment. The eyeglasses 2600 have a photoelectric conversion device 2602. The photoelectric conversion device 2602 is the photoelectric conversion device (imaging device) according to any one of the embodiments described above. In addition, a display device including a light-emitting device such as an OLED or an LED may be provided on a rear surface side of a lens 2601. There may be one or a plurality of photoelectric conversion devices 2602. Alternatively, a plurality of types of photoelectric conversion devices may be used in combination. An arrangement position of the photoelectric conversion device 2602 is not limited to that shown in FIG. 26A.

The eyeglasses 2600 further include a control device 2603. The control device 2603 functions as a power source that supplies power to the photoelectric conversion device 2602 and the display device described above. In addition, the control device 2603 controls operations of the photoelectric conversion device 2602 and the display device. An optical system for collecting light to the photoelectric conversion device 2602 is formed in the lens 2601.

FIG. 26B illustrates eyeglasses 2610 (smart glasses) according to one application example. The eyeglasses 2610 include a control device 2612 and the control device 2612 is mounted with a photoelectric conversion device that corresponds to the photoelectric conversion device 2602 and a display device. An optical system for projecting light emitted from the photoelectric conversion device inside the control device 2612 and the display device is formed in the lens 2611 and an image is projected onto the lens 2611. The control device 2612 functions as a power source that supplies power to the photoelectric conversion device and the display device and, at the same time, controls operations of the photoelectric conversion device and the display device. The control device may have a line-of-sight detecting unit that detects a line-of-sight of a wearer. Infrared light may be used to detect a line-of-sight. An infrared light-emitting unit emits infrared light to the eyes of a user who is looking at a display image. A picked-up image of the eyes can be obtained by having an imaging unit including a light-receiving element detect reflected light from the eyes of emitted infrared light. Providing reducing means that reduces light from the infrared light-emitting unit to the display unit in a plan view enables a decline in image quality to be mitigated.

A line-of-sight of the user with respect to a display image can be detected from a picked-up image of eyes obtained by imaging with infrared light. Any known method can be applied to line-of-sight detection using a picked-up image of the eyes. For example, a line-of-sight detection method based on a Purkinje image due to reflection of irradiation light by the cornea can be used.

More specifically, line-of-sight detection processing based on a pupil-corneal reflection method is performed. Using the pupil-corneal reflection method, a line-of-sight of a user is detected by calculating a line-of-sight vector that represents an orientation (a rotation angle) of the eyes based on an image of a pupil included in a picked-up image of the eyes and a Purkinje image. The display device according to the present embodiment may have a photoelectric conversion device including a light-receiving element and a display image of the display device may be controlled based on line-of-sight information of the user from the photoelectric conversion device.

Specifically, the display device determines, based on the line-of-sight information, a first field-of-view region which the user focuses on and a second field-of-view region other than the first field-of-view region. The first field-of-view region and the second field-of-view region may be determined by the control device of the display device or regions determined by an outside control device may be received as the first field-of-view region and the second field-of-view region. In a display region of the display device, a display resolution of the first field-of-view region may be controlled to be higher than a display resolution of the second field-of-view region. In other words, the resolution of the second field-of-view region may be set lower than that of the first field-of-view region.

In addition, the display region may have a first display region and a second display region that differs from the first display region, and a region with high priority may be determined from the first display region and the second display region based on line-of-sight information. The first display region and the second display region may be determined by the control device of the display device or regions determined by an outside control device may be received as the first display region and the second display region. A resolution of a region with high priority may be controlled to be higher than a resolution of a region other than the region with high priority. In other words, a resolution of a region of which a priority is relatively low can be lowered.

It should be noted that an AI (Artificial Intelligence) may be used to determine the first field-of-view region and a region with high priority. The AI may be a model configured to use an image of the eyes and a direction actually viewed by the eyes in the image as teacher data to estimate, from the image of the eyes, an angle of a line-of-sight and a distance to an object ahead of the line-of-sight. An AI program may be included in the display device, the photoelectric conversion device, or an external device. When the external device includes an AI program, an inference result by an AI is sent to the display device via communication.

Display control based on visual recognition and detection can be preferably applied to smart glasses further including a photoelectric conversion device that captures images of the outside. The smart glasses are capable of displaying captured external information in real-time.

### Eleventh Embodiment

The photoelectric conversion devices and the photoelectric conversion systems described above can be applied to, for example, electronic devices such as so-called smartphones and tablets.

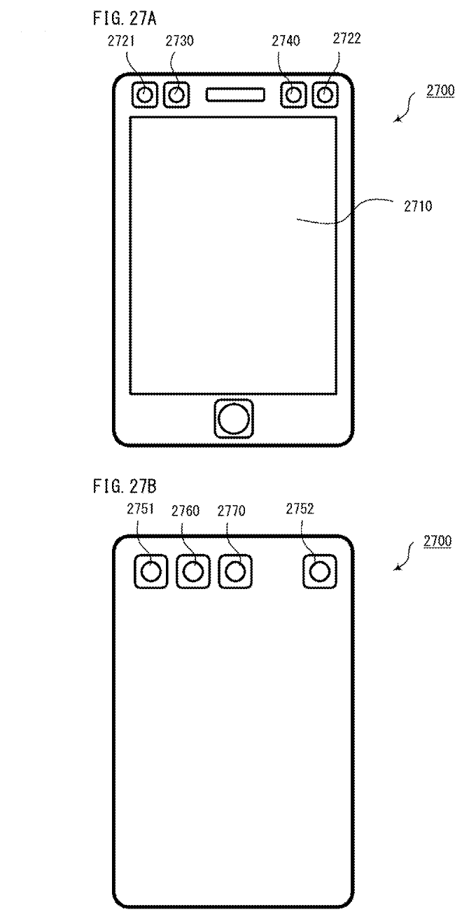

FIGS. 27A and 27B are diagrams showing an example of an electronic device 2700 to which a photoelectric conversion device is mounted. FIG. 27A shows a front surface side of the electronic device 2700 and FIG. 27B shows a rear surface side of the electronic device 2700.

As shown in FIG. 27A, a display 2710 that displays an image is arranged at a center of the front surface of the electronic device 2700. In addition, front cameras 2721 and 2722 that use the photoelectric conversion device, an IR light source 2730 that emits infrared light, and a visible light source 2740 that emits visible light are arranged along an upper side of the front surface of the electronic device 2700.

Furthermore, as shown in FIG. 27B, rear cameras 2751 and 2752 that use the photoelectric conversion device, an IR light source 2760 that emits infrared light, and a visible light source 2770 that emits visible light are arranged along an upper side of the rear surface of the electronic device 2700.

In the electronic device 2700 configured as described above, by applying the photoelectric conversion device described above, for example, an image with higher quality can be captured and a distance to an object can be measured with high accuracy. Note that the photoelectric conversion device can be applied to other electronic devices such as an infrared sensor, a ranging sensor using an active infrared light source, a security camera, and a personal authentication camera or a biometric camera. As a result, accuracy and performance of such electronic devices can be improved.

### Twelfth Embodiment

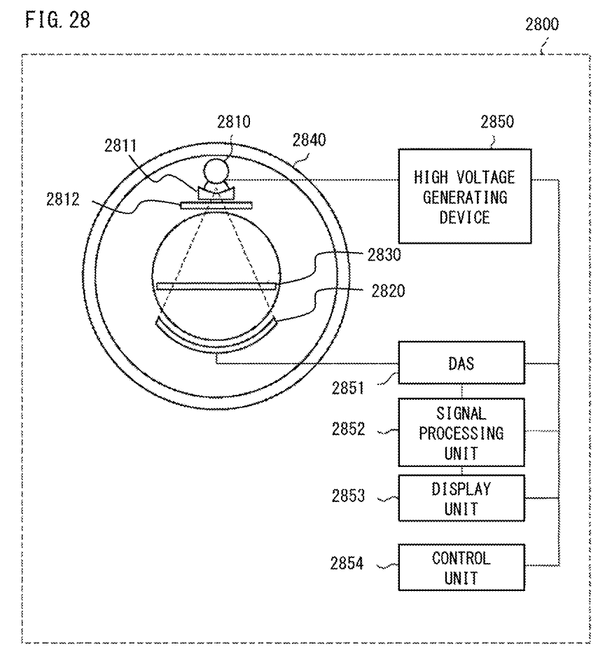

FIG. 28 is a block diagram of an X-ray CT device according to the present embodiment. The photoelectric conversion devices and the photoelectric conversion systems described above can be applied to a detector of the X-ray CT device. An X-ray CT device 2800 according to the present embodiment includes an X-ray generating unit 2810, a wedge 2811, a collimator 2812, an X-ray detecting unit 2820, and a top plate 2830. Furthermore, the X-ray CT device 2800 includes a rotating frame 2840, a high voltage generating device 2850, a data collection device (DAS: Data Acquisition System) 2851, a signal processing unit 2852, a display unit 2853, and a control unit 2854.

The X-ray generating unit 2810 is constituted of, for example, a vacuum tube that generates X-rays. A high voltage from the high voltage generating device 2850 and a filament current are supplied to the vacuum tube of the X-ray generating unit 2810. An X-ray is generated as thermions are radiated from a cathode (filament) toward an anode (target).

The wedge 2811 is a filter that adjusts an X-ray dosage radiated from the X-ray generating unit 2810. The wedge 2811 attenuates the X-ray dosage so that X-rays radiated from the X-ray generating unit 2810 toward the object are distributed as determined in advance. The collimator 2812 is constituted of a lead plate or the like that narrows down an irradiation range of the X-rays having passed through the wedge 2811. An X-ray generated by the X-ray generating unit 2810 is molded into a cone beam shape via the collimator 2812 and radiated to the object on the top plate 2830.

The X-ray detecting unit 2820 is constructed by using the photoelectric conversion device or the photoelectric conversion system described above. The X-ray detecting unit 2820 detects an X-ray having passed through the object from the X-ray generating unit 2810 and outputs a signal corresponding to the X-ray dosage to the DAS 2851.

The rotating frame 2840 has an annular shape and is configured to be rotatable. The X-ray generating unit 2810 (the wedge 2811 and the collimator 2812) and the X-ray detecting unit 2820 are arranged so as to oppose each other inside the rotating frame 2840. The X-ray generating unit 2810 and the X-ray detecting unit 2820 are rotatable together with the rotating frame 2840.

The high voltage generating device 2850 includes a boost circuit and outputs a high voltage to the X-ray generating unit 2810. The DAS 2851 includes an amplifier circuit and an A/D converter circuit and outputs a signal from the X-ray detecting unit 2820 as digital data to the signal processing unit 2852.

The signal processing unit 2852 includes a CPU (Central Processing Unit), a ROM (Read Only Memory), and a RAM (Random Access Memory) and is capable of executing image processing of digital data and the like. The display unit 2853 includes a flat display device or the like and is capable of displaying an X-ray image. The control unit 2854 includes a CPU, a ROM, and a RAM and controls operations of the entire X-ray CT device 2800.

### Thirteenth Embodiment

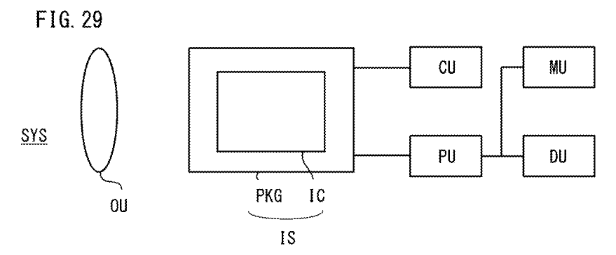

A photoelectric conversion system as an example of equipment according to a tenth embodiment will be described with reference to FIG. 29. FIG. 29 is a block diagram showing a schematic configuration of an imaging system SYS that is the photoelectric conversion system according to the thirteenth embodiment. The imaging system SYS includes at least the photoelectric conversion device according to any one of the embodiments described above and a signal processing unit that processes signals output from the photoelectric conversion device.

The imaging system SYS is an information terminal that includes a camera and a photography function. The imaging system SYS is constructed using an imaging device IS. The imaging device IS can further include a package PKG that houses an imaging device IC. The package PKG can include a substrate on which the imaging device IC is fixed and a lid body that opposes the imaging device IC. The package PKG can include a connecting member (a member that connects a terminal provided on the substrate and a terminal provided on the imaging device IC) to each other. The imaging device IS can mount a plurality of the imaging devices IC to a common package PKG by arranging the imaging devices IC side by side. Alternatively, the imaging device IS can mount the imaging device IC and another semiconductor device IC to a common package PKG by stacking the imaging device IC and the semiconductor device IC on top of each other.

The imaging system SYS can include an optical system OU (optical device) that forms an image on the imaging device IS. In addition, the imaging system SYS can include at least any of a control device CU, a processing device PU, a display device DU, and a storage device MU. The control device CU controls the imaging device IS and the processing device PU processes a signal obtained from the imaging device IS. Furthermore, the display device DU displays an image obtained from the imaging device IS and the storage device MU stores the image obtained from the imaging device IS.

According to the present disclosure, it is possible to provide a trench structure capable of achieving both suppression of deterioration of crosstalk and suppression of a decrease in linearity of signal intensity in a photoelectric conversion device.

Although various devices have been described in the above-described embodiments, mechanical devices may be further provided. A mechanical device in a camera can drive the components of an optical system to perform zooming, focusing, and shutter operations. Alternatively, a mechanical device in a camera can move a photoelectric conversion device for a vibration-insulating operation.

Also, the device can be transportation equipment such as a vehicle, a ship, or a flying object. The mechanical device in transportation equipment can be used as a mobile device. Equipment as transportation equipment is suitable for transportation of a photoelectric conversion device and for assisting and/or automating the operation (maneuvering) by the photographing function. A processing device for assisting and/or automating the operation (maneuvering) can perform processing for operating a mechanical device as a mobile device on the basis of information obtained by the photoelectric conversion device.

Expressions such as "A or B", "at least one of A and B", "at least one of A and/or B", and "one or more of A and/or B" may be used herein. In this case, all possible combinations of enumerated items may be included unless explicitly defined otherwise. That is, it is understood that the expressions disclose all the cases in which at least one A is included, at least one B is included, and at least one A and at least one B are included. This applies similarly to a combination of three or more elements.

The embodiments described above may be appropriately modified without departing from the technical idea. Note that the disclosed content of the present specification includes not only the matters described herein, but also all matters understandable from the present specification and the accompanying drawings attached thereto. The disclosure in the present specification also includes a complement of the concepts described herein. That is, for example, if there is a description of "A is greater than B" in the present specification, even if a description of "A is not greater than B" is omitted, it can be said that the present specification discloses "A is not greater than B". This is because, when "A is greater than B" is described, it is assumed that "A is not greater than B" is considered.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-047301, filed March 21, 2025, which is hereby incorporated by reference herein in its entirety.

What is claimed is:

1. A photoelectric conversion device comprising:
a substrate having a first surface and a second surface that is a surface on a side opposite to the first surface and is a light incident surface,
wherein a plurality of pixels are arranged on the substrate,
the plurality of pixels each have a plurality of photoelectric conversion units,
between the plurality of photoelectric conversion units included in one pixel of the plurality of pixels, a first trench extending from the second surface toward the first surface is arranged,
between the plurality of pixels, a second trench extending from the first surface toward the second surface is arranged,
in a plan view of the substrate, the first trench and the second trench have an intersecting portion where the first trench and the second trench intersect with each other,
the first trench is separated from the first surface, and
an end portion on the first surface side of the first trench in the intersecting portion is positioned on the second surface side relative to an end portion on the first surface side of the first trench in a non-intersecting portion where the first trench and the second trench do not intersect in the plan view.

2. A photoelectric conversion device comprising:
a substrate having a first surface and a second surface that is a surface on a side opposite to the first surface and is a light incident surface,
wherein a plurality of pixels are arranged on the substrate,
the plurality of pixels each have a plurality of photoelectric conversion units,
between the plurality of photoelectric conversion units included in one pixel of the plurality of pixels, a first trench extending from the second surface toward the first surface is arranged,
between the plurality of pixels, a second trench extending from the first surface toward the second surface is arranged,
in a plan view of the substrate, the first trench and the second trench have an intersecting portion where the first trench and the second trench intersect with each other,
the first trench is separated from the first surface, and
an end portion on the second surface side of the second trench in the intersecting portion is positioned on the first surface side relative to an end portion on the second surface side of the second trench in a non-intersecting portion where the first trench and the second trench do not intersect in the plan view.

3. The photoelectric conversion device according to claim 1, wherein an end portion on the first surface side of the first trench is positioned on the first surface side relative to an end portion on the second surface side of the second trench.

4. The photoelectric conversion device according to claim 1, wherein a P-type diffusion layer is arranged on a sidewall portion of the first trench.

5. The photoelectric conversion device according to claim 4, wherein in the P-type diffusion layer, an abundance ratio of boron having a mass number of 10 is less than 10% of the entire boron.

6. The photoelectric conversion device according to claim 1, wherein a P-type diffusion layer is arranged on a sidewall portion of the second trench, and
in the P-type diffusion layer arranged on the sidewall portion of the second trench, an abundance ratio of boron having a mass number of 10 is not less than 10% of the entire boron.

7. The photoelectric conversion device according to claim 1, wherein in a portion where the first trench and the second trench do not intersect each other in the plan view, the second trench extends from the first surface to the second surface.

8. The photoelectric conversion device according to claim 1, wherein a film that retains fixed charges and covers at least a part of the first trench is arranged.

9. A photoelectric conversion device comprising:
a substrate having a first surface and a second surface that is a surface on a side opposite to the first surface and is a light incident surface,
wherein a plurality of pixels are arranged on the substrate,
the plurality of pixels each have a plurality of photoelectric conversion units,
between the plurality of photoelectric conversion units included in one pixel of the plurality of pixels, a first trench extending from the second surface toward the first surface is arranged,
between the plurality of pixels, a second trench extending from the first surface toward the second surface is arranged,
in a plan view of the substrate, the first trench and the second trench do not intersect, and a P-type diffusion layer is arranged between the first trench and the second trench, and
the first trench is separated from the first surface.

10. The photoelectric conversion device according to claim 9, wherein an end portion on the first surface side of the first trench is positioned on the first surface side relative to an end portion on the second surface side of the second trench.

11. The photoelectric conversion device according to claim 9, wherein in the P-type diffusion layer, an abundance ratio of boron having a mass number of 10 is less than 10% of the entire boron.

12. The photoelectric conversion device according to claim 9, wherein a P-type diffusion layer is arranged on a sidewall portion of the second trench, and
in the P-type diffusion layer arranged on the sidewall portion of the second trench, an abundance ratio of boron having a mass number of 10 is not less than 10% of the entire boron.

13. The photoelectric conversion device according to claim 9, wherein in the plan view, the second trench extends from the first surface to the second surface.

14. The photoelectric conversion device according to claim 9, wherein a film that retains fixed charges and covers at least a part of the first trench is arranged.

15. A photoelectric conversion system comprising:
the photoelectric conversion device according to claim 1; and
a signal processing unit that generates an image by using a signal output by the photoelectric conversion device.

16. A mobile body comprising the photoelectric conversion device according to claim 1,
wherein the mobile body includes a control unit that controls a movement of the mobile body by using a signal output by the photoelectric conversion device.

17. Equipment comprising:
the photoelectric conversion device according to claim 1; and
at least any of an optical device corresponding to the photoelectric conversion device;
a control device that controls the photoelectric conversion device;
a processing device that processes a signal output from the photoelectric conversion device;
a display device that displays information obtained by the photoelectric conversion device;
a storage device that stores information obtained by the photoelectric conversion device; and
a mechanical device that operates on the basis of the information obtained by the photoelectric conversion device.
